(19) United States
(12) Patent Application Publication
(10) Pub. No.: US 2024/0237430 A1
(43) Pub. Date: Jul. 11, 2024

(54) IMAGE DISPLAY DEVICE AND ELECTRONIC DEVICE

(71) Applicant: Sony Semiconductor Solutions Corporation, Kanagawa (JP)

(72) Inventor: Seiichiro Jinta, Kanagawa (JP)

(21) Appl. No.: 18/558,614

(22) PCT Filed: Mar. 30, 2022
(86) PCT No.: PCT/JP2022/015937

§ 371 Date: Nov. 2, 2023

(30) Foreign Application Priority Data
Jun. 14, 2021 (JP) 2021-099012

(51) Int. Cl. H10K 59/126; H10K 59/121; H10K 59/131; H10K 59/65

(52) U.S. Cl. CPC H10K 59/126; H10K 59/1213; H10K 59/131; H10K 59/65

(57) ABSTRACT

An object is to block natural light and light source light from being incident on a transistor in a pixel even in a case where a transmission portion is provided.

An image display device includes a plurality of pixels arranged two-dimensionally. The plurality of pixels includes a first pixel region including a pixel that includes a first region configured to emit light and a second region configured to transmit visible light, a second pixel region arranged around the first pixel region, the second pixel region including a pixel configured to emit light with an area larger than a light-emitting area of the pixel in the first pixel region, and a light shielding layer configured to shield a transistor arranged in the second region from light.

### TECHNICAL FIELD

The present disclosure relates to an image display device and an electronic device.

### BACKGROUND ART

In recent electronic devices such as smartphones, mobile phones, and personal computers (PCs), various sensors such as cameras are mounted in a frame (bezel) of a display panel. The number of mounted sensors also tends to increase, and there are a sensor for face authentication, an infrared sensor, a moving object detection sensor, and the like in addition to cameras. Furthermore, in some configurations, a light source for a projector or the like is also mounted. On the other hand, from the viewpoint of design and the tendency of making electronic devices lighter, thinner, shorter, and smaller, an outer size of the electronic device is required to be made as compact as possible without affecting a screen size, causing a bezel width to become narrower. In view of such a background, a technique has been proposed in which an image sensor module is arranged immediately below a display panel, and subject light having passed through the display panel is captured by the image sensor module. In order to arrange the image sensor module immediately below the display panel, it is necessary to make the display panel transparent (see Patent Document 1).

### CITATION LIST

### Patent Document

Patent Document 1: Japanese Patent Application Laid-Open No. 2011-175962

### SUMMARY OF THE INVENTION

### Problems to be Solved by the Invention

In order to make the display panel transparent, it is necessary to provide a transmission portion that transmits visible light in at least some pixels in the display panel. An increase in the area of the transmission portion allows an increase in the number of types of sensors and light sources that can be arranged immediately below the display panel.

Many of the latest display panels, however, have a resolution of full HD or higher, and the number of pixels tends to increase. Furthermore, obtaining an improvement in display quality makes it difficult to reduce the number of transistors in each pixel. It is therefore necessary for some of the transistors in each pixel to be arranged in the transmission portion.

However, there is a possibility that natural light or light source light enters the transmission portion and is incident on the transistors in the transmission portion, which accelerates deterioration of the transistors (source-drain current leakage due to light). The deterioration of the transistors changes a current flowing through the transistors, which causes deterioration in display quality such as a reduction in light emission luminance.

It is therefore an object of the present disclosure to provide an image display device and an electronic device that block natural light and light source light from being incident on a transistor in a pixel even in a case where a transmission portion is provided.

### Solutions to Problems

In order to solve the problem described above, according to the present disclosure, there is provided an image display device including a plurality of pixels arranged two-dimensionally, in which
the plurality of pixels includes:
a first pixel region including a pixel that includes a first region configured to emit light and a second region configured to transmit visible light;
a second pixel region arranged around the first pixel region, the second pixel region including a pixel configured to emit light with an area larger than a light-emitting area of the pixel in the first pixel region; and
a light shielding layer configured to shield a transistor arranged in the second region from light.

The light shielding layer may block at least one of ambient light or light source light from being incident on the transistor arranged in the second region.

The light shielding layer may be arranged so as to block light from being incident on a channel region of the transistor.

The light shielding layer may have an area equal to or larger than an area of the channel region of the transistor.

The light shielding layer may be arranged so as to block light from being incident on a lightly doped drain (LDD) region arranged between the channel region and a source region of the transistor and between the channel region and a drain region of the transistor, and the channel region.

The light shielding layer may have an area equal to or larger than a total area of the channel region of the transistor and the LDD regions on both sides of the channel region.

In a case where a current flows unidirectionally between a drain and a source of the transistor arranged in the second region, the light shielding layer may have one end connected to the source and may be arranged so as to cover a channel region of the transistor.

In a case where a current flows bidirectionally between a source and a drain of the transistor arranged in the second region, the light shielding layer may include a first light shielding region having one end connected to the source and covering at least a part of a channel region of the transistor and a second light shielding region having one end connected to the drain and covering at least a part of the channel region.

Each of the plurality of pixels may include:
a light emitting element; and
a drive transistor configured to drive the light emitting element, and
the light shielding layer shields the drive transistor arranged in the second region from light.

Each of the plurality of pixels may include at least one switch transistor configured to operate in a linear region, and the light shielding layer may shield the switch transistor arranged in the second region from light.

The light shielding layer may shield, from light, the switch transistor configured to control a gate voltage of the drive transistor.

There may be further included
an anode electrode layer of the light emitting element;
a first wiring layer including a gate of the transistor arranged below the anode electrode layer; and
a semiconductor layer including a channel region of the transistor arranged below the first wiring layer, in which
the light shielding layer may be arranged below the semiconductor layer to shield the channel region from light.

There may be further included
an anode electrode layer of the light emitting element;
a semiconductor layer arranged below the anode electrode layer and including a channel region of the transistor arranged in the second region; and
a first wiring layer including a gate arranged below the semiconductor layer, in which
the light shielding layer may be arranged below the first wiring layer to shield the channel region from light.

There may be further included a second wiring layer arranged above the first wiring layer and the semiconductor layer to shield the channel region from light.

The light shielding layer may have an area equal to or larger than an area of the semiconductor layer.

There may be further included a display panel including the plurality of pixels, in which
the first pixel region may be provided at a plurality of places in the display panel.

According to the present disclosure, there is provided an electronic device including:
an image display device including a plurality of pixels arranged two-dimensionally; and
a light receiving device configured to receive light incident through the image display device, in which
the image display device includes the plurality of pixels arranged two-dimensionally, and
the plurality of pixels includes:
a first pixel region including a pixel that includes a first region configured to emit light and a second region configured to transmit visible light;
a second pixel region arranged around the first pixel region, the second pixel region including a pixel configured to emit light with an area larger than a light-emitting area of the pixel in the first pixel region; and
a light shielding layer configured to shield a transistor arranged in the second region from light.

The light receiving device may receive light transmitted through the first pixel region.

There may be further included a light source configured to emit light of a predetermined wavelength that passes through the first pixel region.

The light receiving device may include at least one of: an imaging sensor configured to photoelectrically convert light incident through the second region; a distance measuring sensor configured to receive light incident through the second region to measure a distance; or a temperature sensor configured to measure a temperature on the basis of light incident through the second region.

### BRIEF DESCRIPTION OF DRAWINGS

FIG. 1 is a plan view and a cross-sectional view of an electronic device including an image display device according to a first embodiment.

FIG. 2A is a view illustrating an example in which two sensors are arranged side by side on a back surface side on an upper side of a center of a display panel.

FIG. 2B is a view illustrating an example in which sensors are arranged at four corners of the display panel.

FIG. 3 is a view schematically illustrating a structure of a transmissive pixel in a first pixel region and a structure of a normal pixel in a second pixel region.

FIG. 4 is a cross-sectional view of an image sensor module as an example of a sensor.

FIG. 5 is a view schematically illustrating an optical configuration of the image sensor module.

FIG. 6 is a view for explaining an optical path until light from a subject is formed as an image on an image sensor.

FIG. 7 is a circuit diagram illustrating a basic configuration of a pixel circuit including an OLED.

FIG. 8 is an operation timing diagram of the pixel circuit of FIG. 7.

FIG. 9(a) is a layout view of the pixel circuit arranged below an anode electrode of a color pixel, FIG. 9(b) is a layout view of the second pixel region not overlapping with the sensor, and FIG. 9(c) is a layout view of the first pixel region overlapping with the sensor.

FIG. 10 is a cross-sectional view of the normal pixel in the second pixel region in which a sensor is not arranged immediately below.

FIG. 11 is a cross-sectional view of a display layer.

FIG. 12 is a circuit diagram of a pixel circuit according to a first modification example.

FIG. 13 is an operation timing diagram of the pixel circuit of FIG. 12.

FIG. 14 is a circuit diagram of a pixel circuit according to a second modification example.

FIG. 15 is an operation timing diagram of the pixel circuit of FIG. 13.

FIG. 16 is a circuit diagram of a pixel circuit according to a third modification example.

FIG. 17 is an operation timing diagram of the pixel circuit of FIG. 16.

FIG. 18 is a circuit diagram of a pixel circuit according to a fourth modification example.

FIG. 19 is an operation timing diagram of the pixel circuit of FIG. 18.

FIG. 20 is a circuit diagram of a pixel circuit according to a fifth modification example.

FIG. 21 is an operation timing diagram of the pixel circuit of FIG. 20.

FIG. 22 is a cross-sectional view of a first light emitting region and a non-light emitting region having a top-gate structure in the first pixel region.

FIG. 23 is a cross-sectional view of a first light emitting region and a non-light emitting region having a bottom-gate structure in the first pixel region.

FIG. 24 is a diagram clearly indicating, with a broken line, drive transistors of the pixel circuits of FIGS. 7 and 14.

FIG. 25 is a diagram clearly indicating, with a broken line, transistors having the second highest priority after the drive transistor in terms of the need of being shielded from natural light and light source light.

FIG. 26 is a diagram clearly indicating, with a broken line, transistors having the second highest priority after the drive transistor in terms of the need of being shielded from natural light and light source light.

FIG. 27 is a cross-sectional view illustrating a first example of a light shielding layer.

FIG. 28 is a cross-sectional view illustrating a second example of the light shielding layer.

FIG. 29 is a cross-sectional view illustrating a third example of the light shielding layer.

FIG. 30 is a layout view of a pixel circuit 12 in a case where the light shielding layer is provided for some transistors in the pixel circuit of FIG. 7.

FIG. 31 is a layout view illustrating a modification example of FIG. 20.

FIG. 32 is a view illustrating a pixel structure and a pixel layout of the first pixel region and the second pixel region in the display panel.

FIG. 33 is a diagram illustrating a summary of arrangement locations of the light shielding layer provided in the image display device according to the present disclosure.

FIG. 34A is a view illustrating a cross-sectional structure and a planar layout of a non-light emitting region according to a first example.

FIG. 34B is a view illustrating a cross-sectional structure and a planar layout of a non-light emitting region according to a second example.

FIG. 35A is a view illustrating a cross-sectional structure and a planar layout of a non-light emitting region according to a third example.

FIG. 35B is a view illustrating a cross-sectional structure and a planar layout of a non-light emitting region according to a fourth example.

FIG. 36A is a view illustrating a cross-sectional structure and a planar layout of a non-light emitting region according to a fifth example.

FIG. 36B is a view illustrating a cross-sectional structure and a planar layout of a non-light emitting region according to a sixth example.

FIG. 37A is a view illustrating a cross-sectional structure and a planar layout of a non-light emitting region according to a seventh example.

FIG. 37B is a view illustrating a cross-sectional structure and a planar layout of a non-light emitting region according to an eighth example.

FIG. 38A is a view illustrating a cross-sectional structure and a planar layout of a non-light emitting region according to the seventh example.

FIG. 38B is a view illustrating a cross-sectional structure and a planar layout of a non-light emitting region according to the eighth example.

FIG. 39A is a view illustrating a cross-sectional structure and a planar layout of a non-light emitting region according to a ninth example.

FIG. 39B is a view illustrating a cross-sectional structure and a planar layout of a non-light emitting region according to a tenth example.

FIG. 40A is a view illustrating a cross-sectional structure and a planar layout of a non-light emitting region according to an eleventh example.

FIG. 40B is a view illustrating a cross-sectional structure and a planar layout of a non-light emitting region according to a twelfth example.

FIG. 41 is a circuit diagram corresponding to the pixel circuit of FIG. 7.

FIG. 42 is a circuit diagram corresponding to the pixel circuit of FIG. 12.

FIG. 43 is a circuit diagram corresponding to the pixel circuit of FIG. 14.

FIG. 44 is a circuit diagram corresponding to the pixel circuit of FIG. 18.

FIG. 45 is a circuit diagram corresponding to the pixel circuit of FIG. 20.

FIG. 46 is a view illustrating a cross-sectional structure and a planar layout of a non-light emitting region according to a thirteenth example.

FIG. 47 is a view illustrating a cross-sectional structure and a planar layout of a non-light emitting region according to a fourteenth example.

FIG. 48A is a view illustrating an internal state of a vehicle from a rear side to a front side of the vehicle.

FIG. 48B is a view illustrating an internal state of the vehicle from an oblique rear side to an oblique front side of the vehicle.

FIG. 49A is a front view of a digital camera as a second application example of the electronic device.

FIG. 49B is a rear view of the digital camera.

FIG. 50A is an external view of an HMD as a third application example of the electronic device.

FIG. 50B is an external view of a smart glass.

FIG. 51 is an external view of a television (TV) as a fourth application example of the electronic device.

FIG. 52 is an external view of a smartphone as a fifth application example of the electronic device.

### MODE FOR CARRYING OUT THE INVENTION

Hereinafter, embodiments of an image display device and an electronic device will be described with reference to the drawings. Although principal components of the image display device and the electronic device will be mainly described below, the image display device and the electronic device may include components and functions that are not illustrated or described. The following description does not exclude components and functions that are not illustrated or described.

### First Embodiment

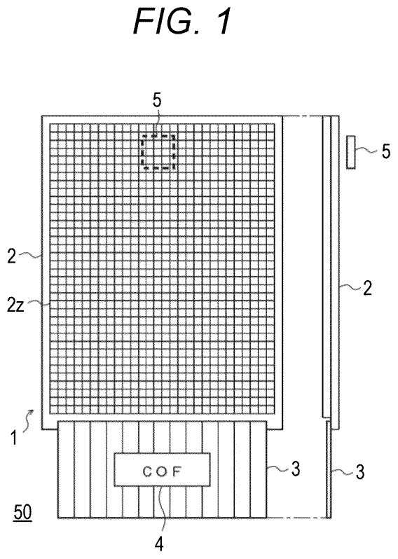

FIG. 1 is a plan view and a cross-sectional view of an electronic device 50 including an image display device 1 according to a first embodiment of the present disclosure. As illustrated, the image display device 1 according to the present embodiment includes a display panel 2. For example, a flexible printed circuit (FPC) 3 is connected to the display panel 2. The display panel 2 is obtained by layering a plurality of layers on, for example, a glass substrate or a transparent film, and a plurality of pixels is arranged vertically and horizontally on a display surface 2z. A chip on film (COF) 4 incorporating at least a part of a drive circuit of the display panel 2 is mounted on the FPC 3. Note that the drive circuit may be layered on the display panel 2 as a chip on glass (COG).

In the image display device 1 according to the present embodiment, various sensors 5 that receive light through the display panel 2 can be arranged immediately below the display panel 2. In the present specification, a configuration including the image display device 1 and the sensor 5 is referred to as the electronic device 50. While a type of the sensor 5 provided in the electronic device 50 is not particularly limited, examples of which include, for example, an imaging sensor 5 that photoelectrically converts light incident through the display panel 2, a distance measuring sensor 5 that projects light through the display panel 2 and receives light reflected by a target object through the display panel 2 to measure a distance to the target object, a temperature sensor 5 that measures a temperature on the basis of light incident through the display panel 2, and the like. In this way, the sensor 5 arranged immediately below the display panel 2 has at least a function of a light receiving device that receives light. Note that the sensor 5 may have a function of a light emitting device that projects light through the display panel 2.

In FIG. 1, an example of a specific location of the sensor 5 arranged immediately below the display panel 2 is indicated by a broken line. As illustrated in FIG. 1, for example, the sensor 5 is arranged on a back surface side on an upper side of a center of the display panel 2. Note that the arrangement location of the sensor 5 in FIG. 1 is an example, and any arrangement location of the sensor 5 may be adopted. By arranging the sensor 5 on the back surface side of the display panel 2, the sensor 5 does not need to be arranged around the display panel 2, a bezel of the electronic device 50 can be minimized, almost the entire region on a front side of the electronic device 50 can be used as the display panel 2, and the outer size of the electronic device 50 can be reduced without having an area of the display panel 2 reduced.

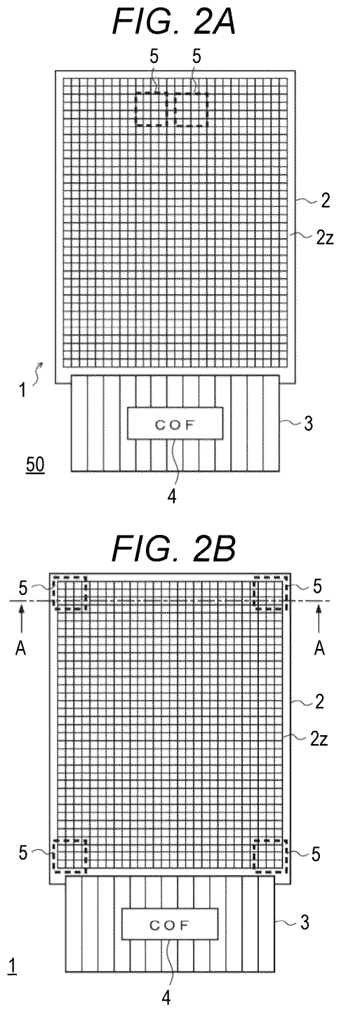

FIG. 1 illustrates an example in which the sensor 5 is arranged at one place of the display panel 2, but the sensor 5 may be arranged at a plurality of places as illustrated in FIG. 2A or 2B. FIG. 2A illustrates an example in which two sensors 5 are arranged side by side on the back surface side on the upper side of the center of the display panel 2. Furthermore, FIG. 2B illustrates an example in which the sensors 5 are arranged at four corners of the display panel 2. As illustrated in FIG. 2B, the sensors 5 are arranged at four corners of the display panel 2 for the following reason. Since a pixel region overlapping with the sensor 5 in the display panel 2 is devised to increase transmittance, there is a possibility that a slight difference occurs in display quality from a surrounding pixel region. When a human gazes at a center of a screen, the human can grasp details of a central portion of the screen, which is a central visual field, and can notice the slight difference. However, a degree of detail visibility of an outer peripheral portion, which is a peripheral visual field, becomes low. Since the center of the screen is often seen in a normal display image, it is recommended to arrange the sensors 5 at the four corners in order to make the difference unnoticeable.

In a case of arranging the plurality of sensors 5 on the back surface side of the display panel 2 as illustrated in FIGS. 2A and 2B, types of the plurality of sensors 5 may be the same or different. For example, a plurality of image sensor modules 9 having different focal lengths may be arranged, or different types of the sensors 5 such as the imaging sensor 5 and a time of flight (ToF) sensor 5 may be arranged.

In a case of arranging the sensor 5 immediately below the display panel 2, it is necessary to change a pixel structure between a pixel region (a first pixel region) overlapping with the sensor 5 on the back surface side and a pixel region (a second pixel region) not overlapping with the sensor 5. Note that, in the present specification, each pixel in the second pixel region may be referred to as a normal pixel, and each pixel in the first pixel region may be referred to as a transmissive pixel.

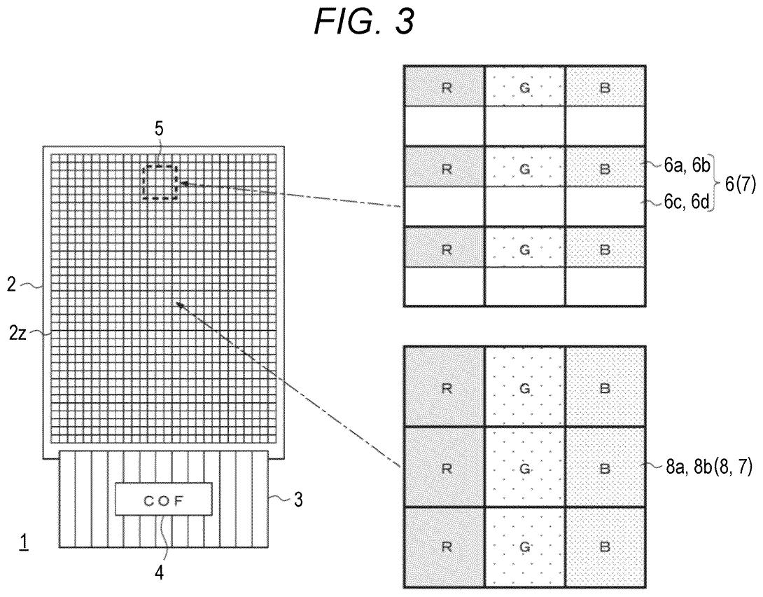

FIG. 3 is a view schematically illustrating a structure of a transmissive pixel 7 in a first pixel region 6 and a structure of a normal pixel 7 in a second pixel region 8. The transmissive pixel 7 in the first pixel region 6 includes a self light-emitting element 6a, a first light emitting region (first region) 6b, and a non-light emitting region (second region) 6c. The first light emitting region 6b is a region in which light is emitted by the self light-emitting element 6a. The non-light emitting region 6c includes a transmissive window 6d having a predetermined shape to transmit visible light although light is not emitted by the self light-emitting element 6a. The normal pixel 7 in the second pixel region 8 includes a self light-emitting element 8a and a second light emitting region 8b. Light is emitted by the self light-emitting element 8a in the second light emitting region 8b, and the second light emitting region 8b has an area larger than that of the first light emitting region 6b. Furthermore, the normal pixel 7 in the second pixel region 8 is not provided with a transmissive window.

Typical examples of the self light-emitting element 6a and the self light-emitting element 8a are organic electroluminescence (EL) elements (hereinafter, also referred to as an organic light emitting diode (OLED)). Since a backlight can be omitted, at least a part of the self light-emitting elements 6a and 8a can be made transparent. Hereinafter, an example in which the OLED is used as the self light-emitting element will be mainly described.

Note that, it is also conceivable to make all the pixels 7 in the display panel 2 have the same structure, instead of changing the structures of the pixels 7 in the pixel region overlapping with the sensor 5 and the pixel region not overlapping with the sensor 5. In this case, it is only required that all the pixels 7 be configured by the first light emitting region 6b and the non-light emitting region 6c in FIG. 3 such that the sensor 5 can be overlapped and arranged at any location in the display panel 2. However, since the first light emitting region 6b has a smaller light-emitting area than the normal pixel, a current per unit area increases, and the OLED is easily deteriorated. Therefore, in the image display device 1 according to the present disclosure, the first pixel region 6 and the second pixel region 8 are provided in the display panel 2.

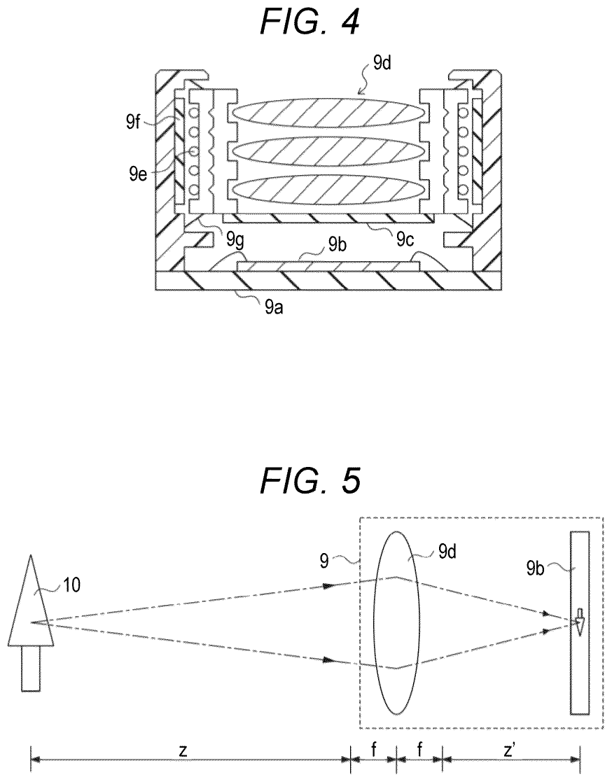

FIG. 4 is a cross-sectional view of the image sensor module 9 which is an example of the sensor 5. As illustrated in FIG. 4, the image sensor module 9 includes an image sensor 9b mounted on a support substrate 9a, an infrared ray (IR) cut filter 9c, a lens unit 9d, a coil 9e, a magnet 9f, and a spring 9g. The lens unit 9d includes one or a plurality of lenses. The lens unit 9d is movable in an optical axis direction in accordance with a direction of a current flowing through the coil 9e. Note that an internal configuration of the image sensor module 9 is not limited to that illustrated in FIG. 4.

FIG. 5 is a view schematically illustrating an optical configuration of the image sensor module 9. Light from a subject 10 is refracted by the lens unit 9d, and formed as an image on the image sensor 9b. As an amount of light incident on the lens unit 9d increases, an amount of light received by the image sensor 9b also increases, and sensitivity improves. In a case of the present embodiment, the display panel 2 is arranged between the subject 10 and the lens unit 9d. When light from the subject 10 is transmitted through the display panel 2, it is important to suppress absorption, reflection, and diffraction in the display panel 2.

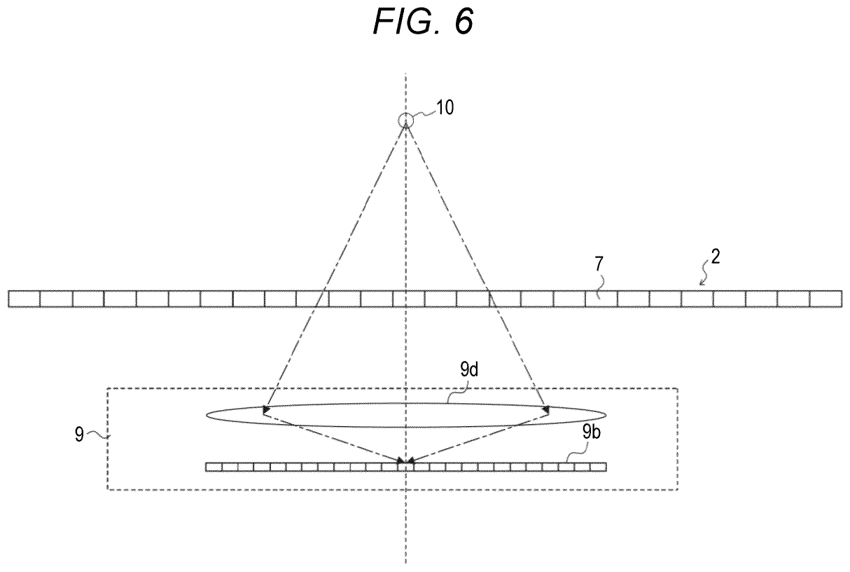

FIG. 6 is a view for explaining an optical path until light from the subject 10 is formed as an image on the image sensor 9b. In FIG. 6, each pixel 7 of the display panel 2 and each pixel 7 of the image sensor 9b are schematically represented by rectangular squares. As illustrated, a size of each pixel 7 of the display panel 2 is much larger than a size of each pixel 7 of the image sensor 9b. Light from a specific position of the subject 10 passes through the transmissive window of the display panel 2, is refracted by the lens unit 9d of the image sensor module 9, and is formed as an image at a specific pixel on the image sensor 9b. As described above, the light from the subject 10 is transmitted through the plurality of transmissive windows provided in the plurality of pixels 7 in the first pixel region 6 of the display panel 2, and is incident on the image sensor module 9.

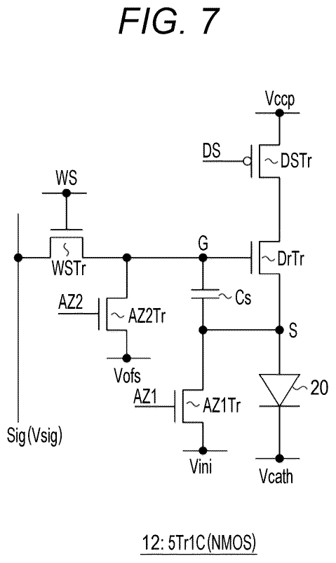

FIG. 7 is a circuit diagram illustrating a basic configuration of a pixel circuit 12 including an OLED 20. The pixel circuit 12 of FIG. 7 includes five transistors Dr, WS, DS, AZ1, and AZ2 and a pixel capacitor Cs in addition to the OLED 20. The transistor Dr is a drive transistor that drives the OLED 20. The drive transistor Dr has a source connected to an anode electrode of the OLED 20. The pixel capacitor Cs is connected between a gate and the source of the drive transistor Dr. The transistor DS is connected between a drain of the drive transistor Dr and a power supply voltage node Vccp. The transistor DS is turned on or off by a DS signal.

The transistor WS is connected between the gate of the drive transistor Dr and a signal line Sig. The transistor WS is a sampling transistor that is turned on or off by a WS signal.

The transistor AZ1 is connected between the source of the drive transistor Dr and an initialization voltage node Vini. The transistor AZ1 is turned on or off by an AZ1 signal. The transistor AZ2 is connected between the gate of the drive transistor Dr and an offset voltage node Vofs. The transistor AZ2 is turned on or off by an AZ2 signal.

Among the five transistors in the pixel circuit 12, only the drive transistor Dr performs an amplification operation in the saturation region, and the other four transistors perform a switching operation in the linear region. Furthermore, among the five transistors, only the transistor DS is a PMOS transistor, and the other four transistors are NMOS transistors.

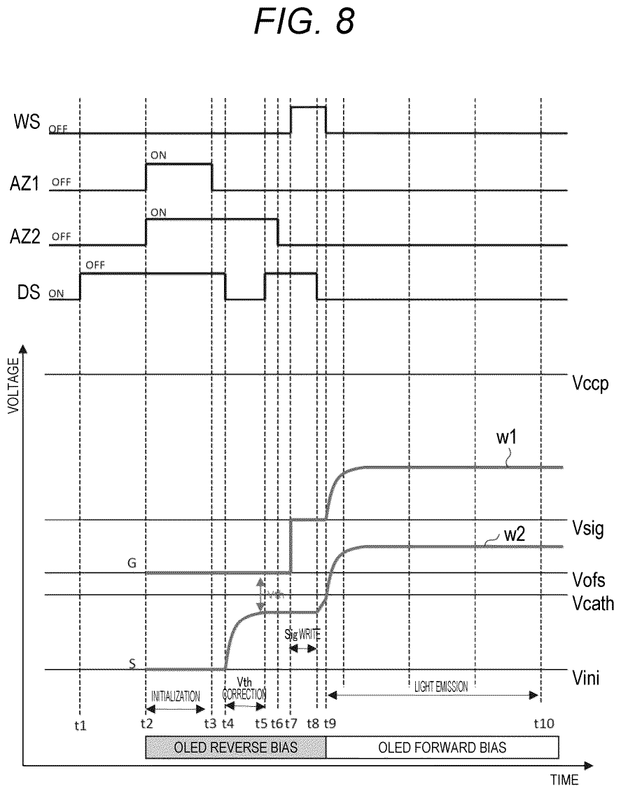

FIG. 8 is an operation timing diagram of the pixel circuit 12 of FIG. 7. At time t1, the transistor DS is turned off. At time t1, the transistors WS, AZ1, and AZ2 are also in an off state. Thereafter, the transistors AZ1 and AZ2 are turned on at time t2. As a result, the source (waveform w2) of the drive transistor Dr becomes the initialization voltage Vini, and the gate (waveform w1) of the drive transistor Dr becomes the offset voltage Vofs. Therefore, at this time point, a voltage of Vofs−Vini is applied to the pixel capacitor Cs connected between the gate and the source of the drive transistor Dr.

At time t3, the AZ1 signal becomes low to turn the transistor AZ1 off, and thereafter, at time t4, the DS signal becomes low to make the transistor DS. As a result, the source voltage of the drive transistor Dr rapidly increases, and when the gate-source voltage of the drive transistor Dr reaches a threshold voltage of the drive transistor Dr, the increase in the source voltage of the drive transistor Dr stops. As a result, a charge according to the gate-source voltage of the drive transistor Dr is applied to the pixel capacitor Cs.

Thereafter, at time t5, the DS signal becomes high to turn the transistor DS off. Subsequently, at time t6, the AZ2 signal becomes low to turn the transistor AZ2 off. As a result, the gate-source voltage of the drive transistor Dr becomes equal to the threshold voltage Vth of the drive transistor Dr.

Thereafter, at time t7, the WS signal becomes high to turn the transistor WS on. As a result, a signal line voltage is applied to the gate of the drive transistor Dr via the signal line Sig and the transistor WS. At this time point, since the transistor DS is off, even if the gate voltage of the drive transistor Dr increases, the source voltage of the drive transistor Dr does not change, and the gate voltage of the drive transistor Dr becomes a voltage corresponding to the signal line voltage.

Thereafter, at time t8, the DS signal becomes low to turn the transistor DS on. A period from time t7 to time t8 is a period for writing the signal line voltage. After time t8, a current flows between the drain and source of the drive transistor Dr, and the source voltage of the drive transistor Dr starts to increase accordingly.

Thereafter, at time t9, the WS signal becomes low to turn the transistor WS off. During a period from time t8 to time t9, a current flows between the drain and source of the drive transistor Dr with the gate of the drive transistor Dr held at the signal line voltage. The source voltage of the drive transistor Dr is lower than the gate voltage of the drive transistor Dr by the threshold voltage, but the OLED 20 can be regarded as a capacitor by setting the source voltage lower than a light emission threshold voltage of the OLED 20. That is, the drain-source current of the drive transistor Dr flows to the pixel capacitor Cs and the equivalent capacitor of the OLED 20, and the source voltage of the drive transistor Dr increases accordingly. The increase ΔV in the source voltage of the drive transistor Dr is subtracted from the gate-source voltage Vgs of the drive transistor Dr held by the pixel capacitor Cs, which corresponds to the application of negative feedback.

As described above, it is possible to correct mobility u of the drive transistor Dr by negatively feeding the drain-source current of the drive transistor Dr back to the Vgs of the drive transistor Dr. Note that the negative feedback amount ΔV can be optimized by adjusting a time width from time t8 to time t9.

After time t9, the gate of the drive transistor Dr is separated from the signal line, so that the gate voltage of the drive transistor Dr is held at (Vsig−ΔV+Vth). After time t9, the source voltage and the gate voltage of the drive transistor Dr gradually increase, which brings the OLED 20 out of a reverse bias state and causes the OLED 20 to start to emit light.

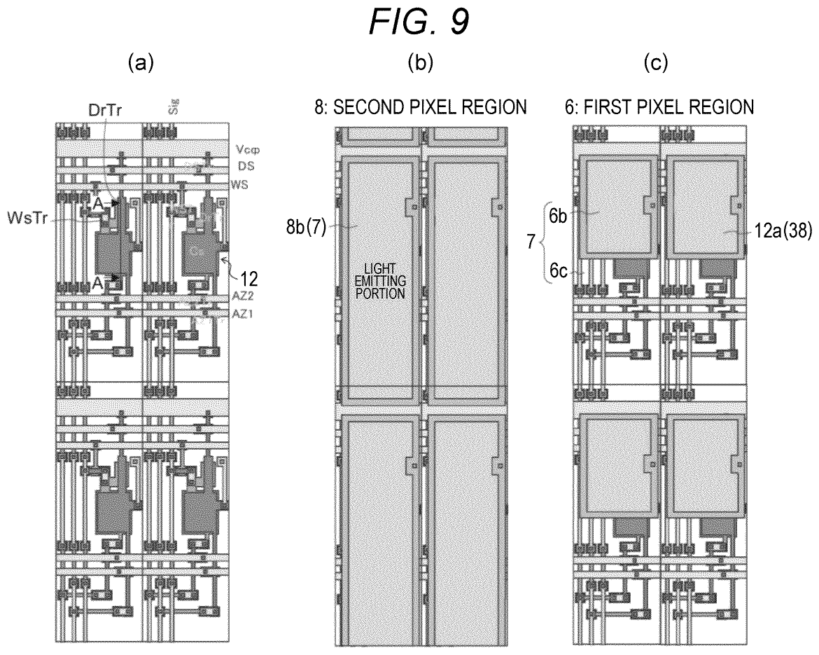

FIGS. 9(a) to 9(c) are layout views of pixels 7 in the display panel 2 including the pixel circuit 12 of FIG. 7. FIGS. 9(a) to 9(c) each illustrate a planar layout of a total of four color pixels 7 including two color pixels 7 horizontally and two color pixels 7 vertically. FIG. 9(a) is a layout view of the pixel circuit 12 arranged below the anode electrodes of the color pixels 7, FIG. 9(b) is a layout view of the second pixel region 8 not overlapping with the sensor 5, and FIG. 9(c) is a layout view of the first pixel region 6 overlapping with the sensor 5.

The pixel circuit 12 of FIG. 7 is arranged in a part of the color pixel 7 in the second pixel region 8. Light emitted by the self light-emitting element 8a in the pixel circuit 12 is emitted in almost the entire region of the normal pixel 7. Therefore, as illustrated in FIG. 9(b), almost the entire region of the color pixel 7 becomes the second light emitting region 8b.

On the other hand, the transmissive pixel (the color pixel) 7 in the first pixel region 6 includes the first light emitting region 6b and the non-light emitting region 6c as illustrated in FIG. 9(c). The pixel circuit 12 is arranged in the first light emitting region 6b, and light emitted from the self light-emitting element 6a in the pixel circuit 12 is emitted in the first light emitting region 6b and is not emitted in the non-light emitting region 6c. As described above, the color pixel 7 in the first pixel region 6 emits light with an area smaller than that of the color pixel 7 in the second pixel region 8. FIG. 9(c) illustrates an example in which about an upper half of the color pixel 7 in the first pixel region 6 is the first light emitting region 6b, and about a lower half of the color pixel 7 is the non-light emitting region 6c.

As illustrated in FIG. 9(a), on an upper end side of the color pixel 7, a wiring pattern for the power supply voltage Vccp and a wiring pattern for a scanning line are arranged in a horizontal direction X. Furthermore, a wiring pattern of the signal line Sig is arranged along a boundary of the color pixel 7 in a vertical direction Y. The arrangement locations of these wiring patterns are merely an example.

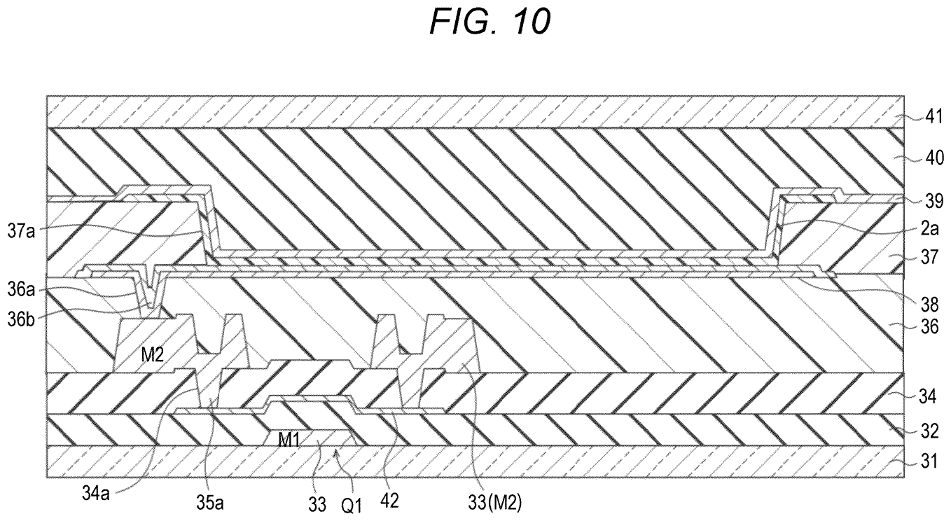

FIG. 10 is a cross-sectional view of the normal pixel 7 (the color pixel 7) in the second pixel region 8 in which the sensor 5 is not arranged immediately below. FIG. 10 illustrates a cross-sectional structure in a direction of A-A line of FIG. 9, and more specifically illustrates a cross-sectional structure around the drive transistor Dr in the pixel circuit 12. Note that the cross-sectional views illustrated in the drawings attached to the present specification, including FIG. 10, emphasize and illustrate a characteristic layer configuration, and a ratio of vertical and horizontal lengths does not necessarily coincide with a planar layout.

An upper surface in FIG. 10 is a display surface side of the display panel 2, and a bottom surface in FIG. 10 is a side on which the sensor 5 is arranged. From the bottom surface side to the upper surface side (a light emission side) in FIG. 10, a first transparent substrate 31, a first insulating layer 32, a first wiring layer (a gate electrode) 33, a second insulating layer 34, a second wiring layer (source wiring or drain wiring) 35, a third insulating layer 36, an anode electrode layer 38, a fourth insulating layer 37, a display layer 2a, a cathode electrode layer 39, a fifth insulating layer 40, and a second transparent substrate 41 are sequentially layered.

The first transparent substrate 31 and the second transparent substrate 41 are desirably formed by, for example, quartz glass, a transparent film, or the like having excellent visible light transmittance. Alternatively, either one of the first transparent substrate 31 and the second transparent substrate 41 may be formed by quartz glass, and the other one may be formed by a transparent film.

Note that, from the viewpoint of production, a colored film having a relatively low transmittance, for example, a polyimide film may be used. Alternatively, at least one of the first transparent substrate 31 or the second transparent substrate 41 may be formed by a transparent film. On the first transparent substrate 31, the first wiring layer (M1) 33 for connection of each circuit element in the pixel circuit 12 is arranged.

On the first transparent substrate 31, the first insulating layer 32 is arranged so as to cover the first wiring layer 33. The first insulating layer 32 has, for example, a layered structure of a silicon nitride layer and a silicon oxide layer excellent in visible light transmittance. On the first insulating layer 32, a semiconductor layer 42 in which a channel region of each transistor in the pixel circuit 12 is formed is arranged. FIG. 10 schematically illustrates a cross-sectional structure of the drive transistor Dr including a gate formed in the first wiring layer 33, a source and a drain formed in the second wiring layer 35, and a channel region formed in the semiconductor layer 42, but other transistors are also arranged in these layers 33, 35, and 42, and are connected to the first wiring layer 33 by contacts (not illustrated).

On the first insulating layer 32, the second insulating layer 34 is arranged so as to cover the transistor and the like. The second insulating layer 34 has, for example, a layered structure of a silicon oxide layer, a silicon nitride layer, and a silicon oxide layer having excellent visible light transmittance. A trench 34a is formed in a part of the second insulating layer 34, and the second wiring layer (M2) 35 connected to a source, a drain, and the like of each transistor is formed by filling a contact member 35a in the trench 34a. FIG. 10 illustrates the second wiring layer 35 for connection of the drive transistor Dr and the anode electrode of the OLED 20, but the second wiring layer 35 connected to other circuit elements is also arranged in the same layer. Furthermore, as described later, a third wiring layer (not illustrated in FIG. 10) may be provided between the second wiring layer 35 and the anode electrode. The third wiring layer can be used as wiring in the pixel circuit 12, and may also be used for connection with the anode electrode.

On the second insulating layer 34, the third insulating layer 36 that covers the second wiring layer 35 to planarize a surface is arranged. The third insulating layer 36 is formed by a resin material such as an acrylic resin. A film thickness of the third insulating layer 36 is made larger than a film thicknesses of the first to second insulating layers 32 and 34.

A trench 36a is formed on a part of an upper surface of the third insulating layer 36, a contact member 36b is filled in the trench 36a to achieve conduction with the second wiring layer 35, and the anode electrode layer 38 is formed by extending the contact member 36b to the upper surface side of the third insulating layer 36. The anode electrode layer 38 has a layered structure, and includes a metal material layer. The metal material layer generally has low visible light transmittance, and functions as a reflection layer that reflects light. As a specific metal material, for example, AlNd or Ag can be applied.

Since a lowermost layer of the anode electrode layer 38 is a portion in contact with the trench 36a and is easily disconnected, at least a corner portion of the trench 36a may be formed by a metal material such as AlNd, for example. An uppermost layer of the anode electrode layer 38 is formed by a transparent conductive layer such as indium tin oxide (ITO). Alternatively, the anode electrode layer 38 may have, for example, a layered structure of ITO/Ag/ITO. Ag is originally opaque, but the visible light transmittance is improved by reducing a film thickness. While strength is weakened when Ag is thinned, the anode electrode layer 38 can be made function as a transparent conductive layer by having the layered structure with ITO arranged on both surfaces.

On the third insulating layer 36, the fourth insulating layer 37 is arranged so as to cover the anode electrode layer 38. Similarly to the third insulating layer 36, the fourth insulating layer 37 is also formed by a resin material such as an acrylic resin. The fourth insulating layer 37 is patterned in accordance with an arrangement location of the OLED 20, and a recess 37a is formed.

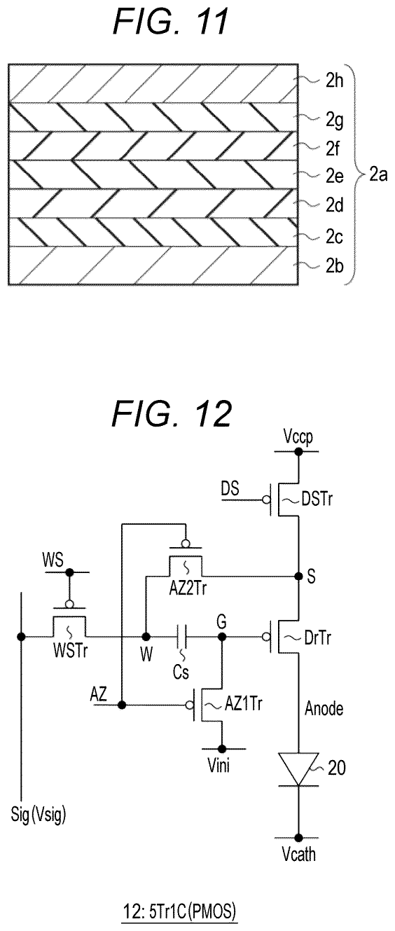

The display layer 2a is arranged so as to include a bottom surface and a side surface of the recess 37a of the fourth insulating layer 37. The display layer 2a has, for example, a layered structure as illustrated in FIG. 11. The display layer 2a illustrated in FIG. 11 has a layered structure in which an anode 2b, a hole injection layer 2c, a hole transport layer 2d, a light-emitting layer 2e, an electron transport layer 2f, an electron injection layer 2g, and a cathode 2h are arranged in a layering order from the anode electrode layer 38 side. The anode 2b is also referred to as an anode electrode. The hole injection layer 2c is a layer into which positive holes from the anode electrode are injected. The hole transport layer 2d is a layer that efficiently transports positive holes to the light-emitting layer 2e. The light-emitting layer 2e recombines positive holes and electrons to generate excitons, and emits light when the excitons return to a ground state. The cathode 2h is also referred to as a cathode electrode. The electron injection layer 2g is a layer into which electrons from the cathode 2h are injected. The electron transport layer 2f is a layer that efficiently transports electrons to the light-emitting layer 2e. The light-emitting layer 2e contains an organic substance.

The cathode electrode layer 39 is arranged on the display layer 2a illustrated in FIG. 10. The cathode electrode layer 39 is formed by a transparent conductive layer similarly to the anode electrode layer 38. Note that, the transparent conductive layer of the anode electrode layer 38 is formed by, for example, ITO/Ag/ITO, and the transparent electrode layer of the cathode electrode layer 39 is formed by, for example, MgAg (which becomes a semi-transparent electrode by thinning) having a film thickness of several nm to several tens of nm or indium zinc oxide (IZO; a transparent electrode) having a film thickness of several tens of nm to several hundreds of nm.

The fifth insulating layer 40 is arranged on the cathode electrode layer 39. The fifth insulating layer 40 planarizes an upper surface and is formed by an insulating material excellent in moisture resistance. The second transparent substrate 41 is arranged on the fifth insulating layer 40.

As illustrated in FIGS. 9(b) and 10, in the second pixel region 8, the anode electrode layer 38 functioning as a reflective film is arranged in almost the entire region of the color pixel 7, and visible light cannot be transmitted. As illustrated in FIG. 9(c), a wiring pattern and the like of the pixel circuit 12 are arranged in the non-light emitting region 6c. Even if the wiring pattern and the like of the pixel circuit 12 are arranged in the non-light emitting region 6c, visible light can be transmitted through a gap of the wiring pattern and the like, so that the non-light emitting region 6c functions as a transmissive window that allows light to be incident on the sensor 5.

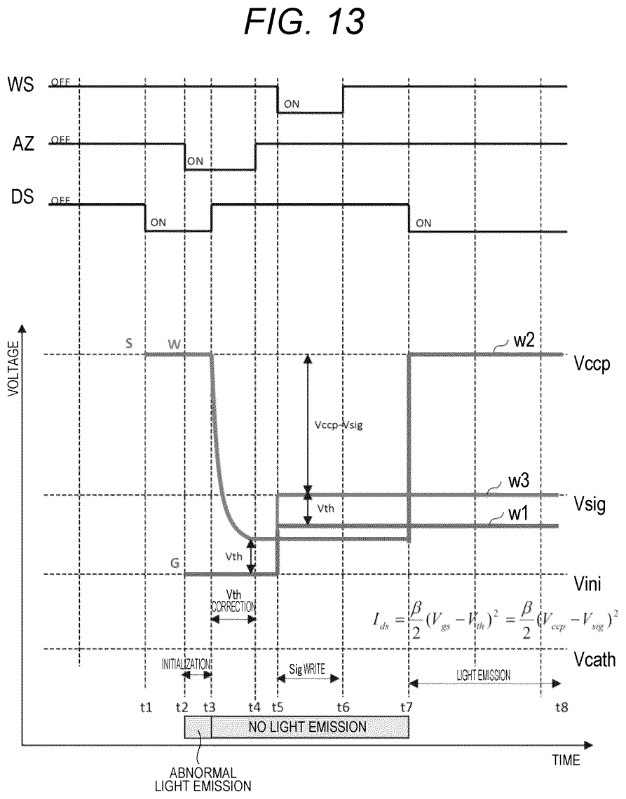

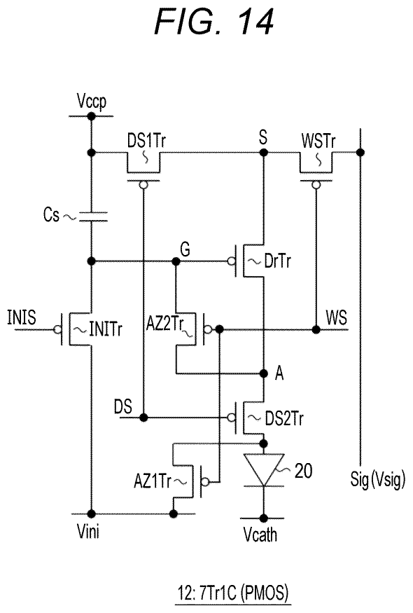

The circuit configuration of the pixel circuit 12 is not limited to the circuit configuration illustrated in FIG. 7, and various circuit configurations are possible. FIG. 12 is a circuit diagram of a pixel circuit 12 according to a first modification example, and FIG. 13 is an operation timing diagram of the pixel circuit 12 of FIG. 12. The pixel circuit 12 of FIG. 12 includes five transistors Dr, WS, DS, AZ1, and AZ2 and a pixel capacitor Cs, similarly to FIG. 7. The five transistors Dr, WS, DS, AZ1, and AZ2 are all PMOS transistors. The pixel circuit 12 of FIG. 12 is characterized in that it includes only PMOS transistors, and is almost identical in circuit operation to the pixel circuit 12 of FIG. 7. The roles of the five transistors Dr, WS, DS, AZ1, and AZ2 in FIG. 12 are also similar to the roles of the five transistors Dr, WS, DS, AZ1, and AZ2 in FIG. 7. Therefore, in the present specification, no description is given of either the circuit configuration or the operation of the pixel circuit 12 of FIG. 12.

The PMOS transistor is lower in mobility than the NMOS transistor, and thus has low off-leakage. Furthermore, the drive transistor Dr is characterized in that the lower the mobility, the easier the control (for example, the lower the mobility of Dr, the more slowly a correction operation such as a mobility correction that is required to be set at the optimum time proceeds, and thus a time setting margin can be made wider, or it becomes robust against variations in correction time), and the operation as the pixel circuit 12 can be made more stable. Furthermore, as described later, the PMOS transistor lower in mobility need not necessarily be provided with a lightly doped drain (LDD) region for electric field relaxation between the channel region and the source/drain region, so that the production process can be simplified as compared with the NMOS transistor.

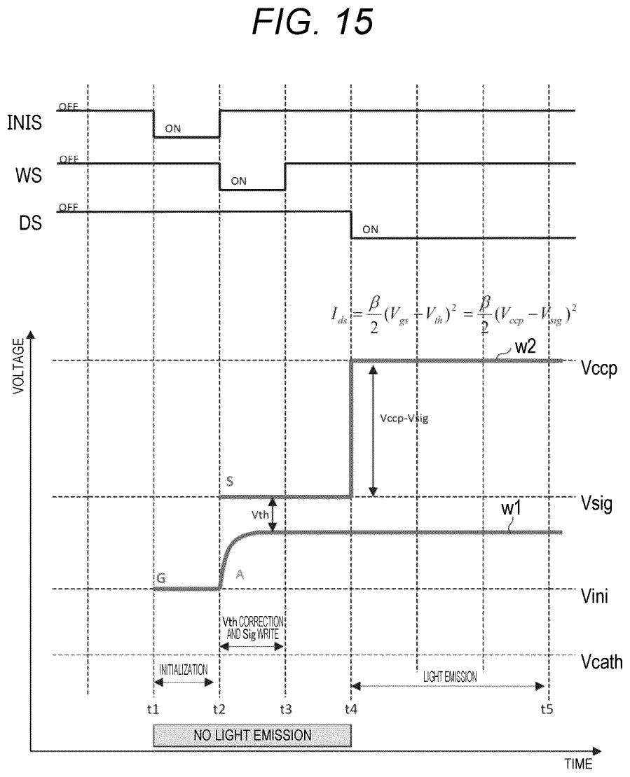

FIG. 14 is a circuit diagram of a pixel circuit 12 according to a second modification example, and FIG. 15 is an operation timing diagram of the pixel circuit 12 of FIG. 13. The pixel circuit 12 of FIG. 14 includes seven transistors Dr, WS, DS1, DS2, AZ1, AZ2, and INI, and a pixel circuit 12. These seven transistors are all PMOS transistors. Note that at least some of the seven transistors may be configured by NMOS transistors, but the description thereof is omitted in the present specification.

The drive transistor Dr has its source connected to both the sources of the transistors WS and DS1 in FIG. 14. The drive transistor Dr has its gate connected to both the sources of the transistors AZ2 and INI and one end of the pixel capacitor Cs. The drive transistor Dr has its drain connected to the source of the transistor DS2 and the drain of the transistor AZ2.

The transistor WS has its drain connected to the signal line. The WS signal is applied to both the gates of the transistors WS, AZ1, and AZ2. The transistor DS1 has its drain connected to the power supply voltage node Vccp and the other end of the pixel capacitor Cs. The initialization voltage Vini is applied to both the drains of the transistors INI and AZ1. The DS signal is input to both the gates of the transistors DS1 and DS2. The transistor DS2 has its drain connected to the anode electrode of the OLED 20, and a cathode voltage Vcath is applied to the cathode electrode of the OLED 20.

In the pixel circuit 12 of FIG. 14, as illustrated in the operation timing diagram of FIG. 15, an INIS signal becomes low during a period from time t1 to time t2, and the gate voltage (waveform w1) of the drive transistor Dr is initially set at the initialization voltage Vini. At time t2, the INIS signal becomes high, and the WS signal becomes low, so that the transistor INI is turned off, and the transistors AZ1 and AZ2 are turned on. As a result, when the gate voltage of the drive transistor Dr increases, and the gate-source voltage of the drive transistor Dr becomes equal to the threshold voltage of the drive transistor Dr, the increase in the gate voltage of the drive transistor Dr stops.

Thereafter, at time t4, the DS signal becomes low to turn the transistor DS1 on. As a result, the source voltage (waveform w2) of the drive transistor Dr rapidly increases, and the OLED 20 starts to emit light.

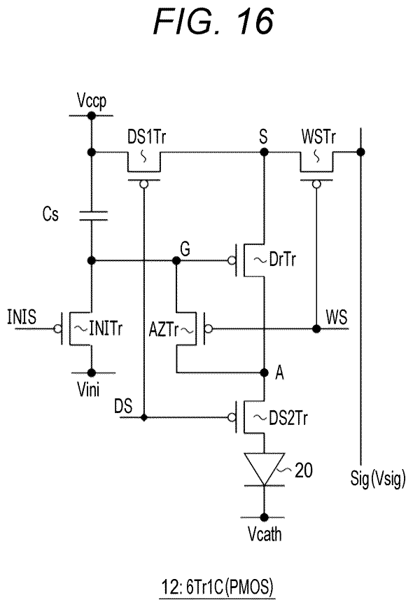

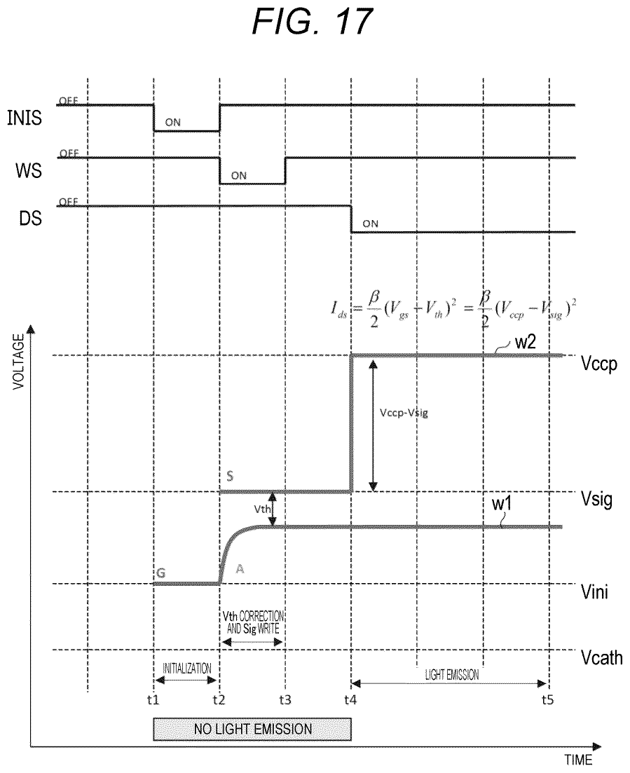

FIG. 16 is a circuit diagram of a pixel circuit 12 according to a third modification example, and FIG. 17 is an operation timing diagram of the pixel circuit 12 of FIG. 16. The pixel circuit 12 of FIG. 16 is obtained by simplifying the pixel circuit 12 of FIG. 14, and includes six transistors Dr, WS, DS1, DS2, AZ, and INI, and a pixel circuit 12. That is, the pixel circuit 12 of FIG. 16 has a configuration without the transistor AZ1 in the pixel circuit 12 of FIG. 14. These six transistors are all PMOS transistors.

The pixel circuit 12 of FIG. 16 is substantially identical in circuit operation to the pixel circuit 12 of FIG. 14, so that the description of the circuit operation is omitted in the present specification.

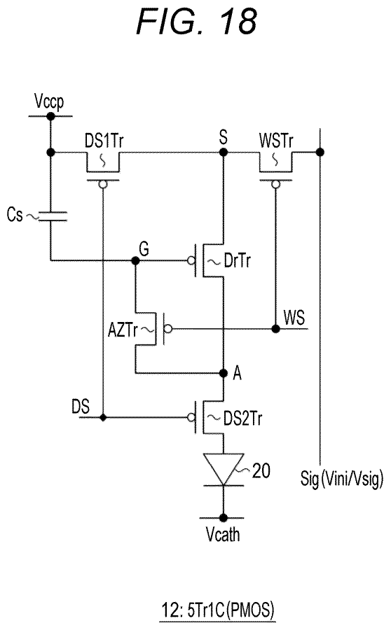

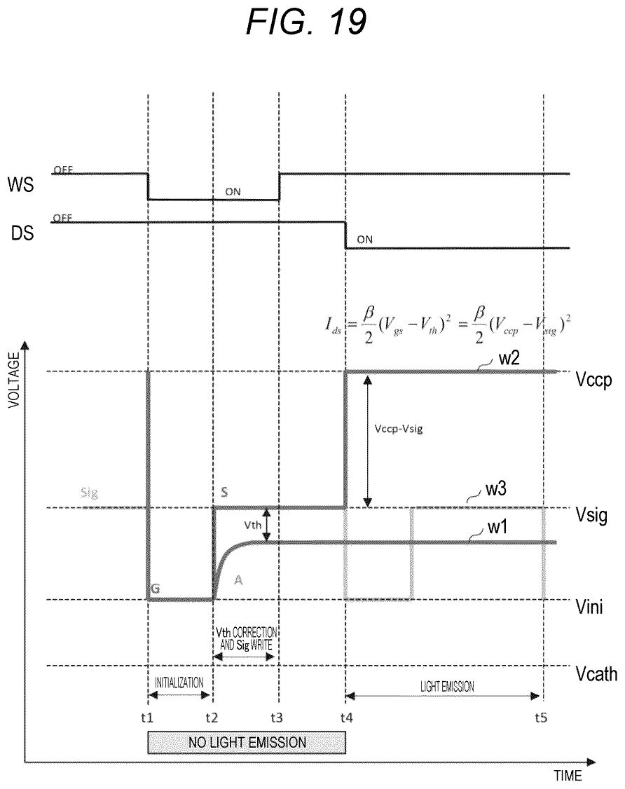

FIG. 18 is a circuit diagram of a pixel circuit 12 according to a fourth modification example, and FIG. 19 is an operation timing diagram of the pixel circuit 12 of FIG. 18. The pixel circuit 12 of FIG. 18 is obtained by simplifying the pixel circuit 12 of FIG. 16, and includes five transistors Dr, WS, DS1, DS2, and AZ, and a pixel circuit 12. That is, the pixel circuit 12 of FIG. 18 has a configuration without the transistor INI in the pixel circuit 12 of FIG. 16. These five transistors are all PMOS transistors.

As illustrated in FIG. 19, at time t1, the WS signal becomes low to turn the transistor WS on, and the source voltage (waveform w2) of the drive transistor Dr decreases according to the signal line voltage (waveform w3). Furthermore, at time t1, the transistor AZ is turned on, the gate voltage (waveform w1) of the drive transistor Dr gradually increases, and when the gate-source voltage of the drive transistor Dr becomes equal to the threshold voltage of the drive transistor Dr, the increase in the gate voltage of the drive transistor Dr stops. Thereafter, at time t3, the WS becomes high to turn the transistor WS off. A period from time t2 to time t3 is a period for writing the signal line voltage and correcting the threshold voltage of the drive transistor Dr.

Thereafter, at time t4, the DS signal becomes low to turn the transistor DS1 on, the source voltage of the drive transistor Dr rapidly increases, and the OLED 20 starts to emit light.

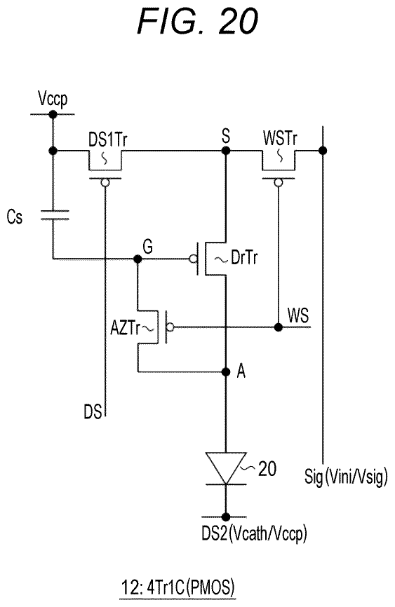

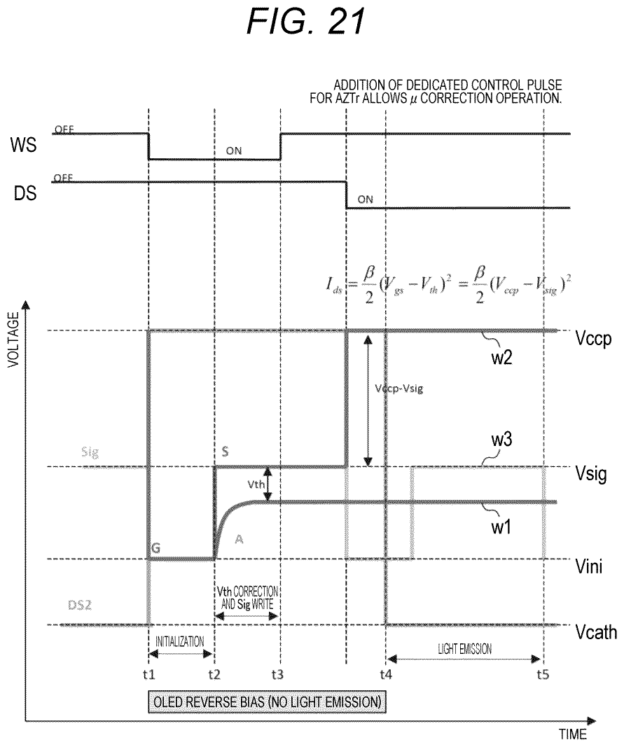

FIG. 20 is a circuit diagram of a pixel circuit 12 according to a fifth modification example, and FIG. 21 is an operation timing diagram of the pixel circuit 12 in FIG. 20. The pixel circuit 12 in FIG. 20 is obtained by simplifying the pixel circuit 12 in FIG. 18, and includes four transistors Dr, WS, DS1, and AZ, and a pixel circuit 12. That is, the pixel circuit 12 in FIG. 20 has a configuration without the transistor DS2 in the pixel circuit 12 in FIG. 18. These four transistors are all PMOS transistors.

In the circuit of FIG. 20, a voltage DS2 (waveform w4) is applied to the cathode of the OLED 20. The voltage DS2 is set at Vcath before time t1 and after time t4, and is set at the voltage Vccp during a period from time t1 to time t4. The circuit of FIG. 20 is similar in operation to the circuit in FIG. 18, so that the description of the circuit is omitted.

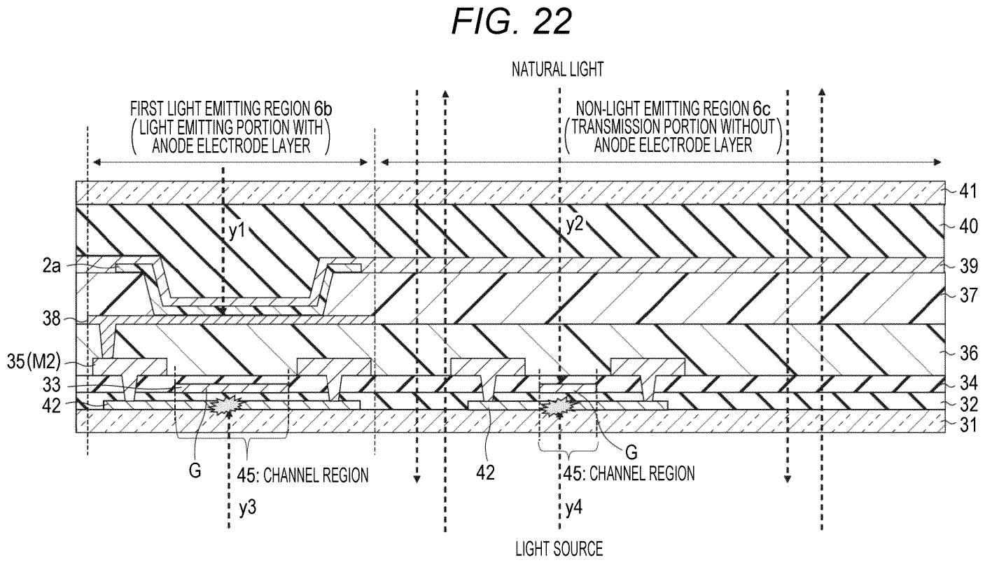

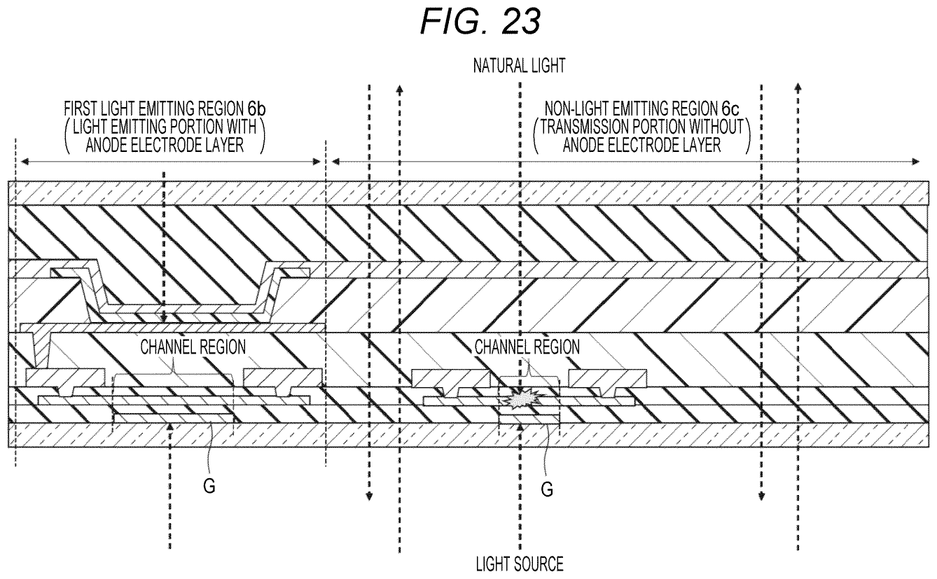

FIGS. 22 and 23 are diagrams for explaining a problem to be solved by the image display device 1 according to the present disclosure. FIGS. 22 and 23 illustrate cross-sectional views of the first light emitting region 6b and the non-light emitting region 6c in the first pixel region 6.

Each transistor in the pixel circuit 12 illustrated in FIGS. 7 to 21 has a top-gate structure or a bottom-gate structure. FIG. 22 illustrates an example including a transistor having a top-gate structure, and FIG. 23 illustrates an example including a transistor having a bottom-gate structure.

In a case of a top-gate structure, as illustrated in FIG. 22, a gate G of the transistor is arranged in the first wiring layer (M1) 33, and the semiconductor layer 42 in which a channel region 45 is formed is arranged below the gate G. As illustrated in FIGS. 7 to 21, a plurality of transistors is arranged in the pixel circuit 12, the transistor in the first light emitting region 6b is arranged below the anode electrode layer 38 as illustrated in FIG. 22, and the transistor in the non-light emitting region 6c is arranged in a region where the anode electrode layer 38 is not arranged.

Natural light (also referred to as ambient light) is incident from the front surface side of the display panel 2 (upper side of FIG. 22), but since the anode electrode layer 38 is arranged in almost the entire first light emitting region 6b, the natural light (arrow line y1) is blocked by the anode electrode layer 38, and there is no possibility that the natural light is incident on the channel region 45. On the other hand, since the anode electrode layer 38 is not arranged in the non-light emitting region 6c, there is a possibility that the natural light (arrow line y2) is incident on the channel region 45 of the transistor.

In the top-gate structure illustrated in FIG. 22, since the gate G is present above the channel region 45, the gate G can block the natural light, but there is a possibility that the natural light having passed through the periphery of the gate G reaches the channel region 45. In particular, in a case where the transistor in the pixel circuit 12 is an NMOS transistor, the LDD region is typically arranged between the channel region 45 and the source/drain region; therefore, even if the gate G is arranged above the channel region 45, there is a possibility that the natural light is incident on at least the LDD region.

Furthermore, in the bottom-gate structure illustrated in FIG. 23, since no light shielding member is present above the channel region 45 of the transistor in the non-light emitting region 6c, there is a possibility that the natural light is directly incident on the channel region 45.

Furthermore, in a case where the light source is arranged on the back surface side in the first pixel region 6, light (hereinafter, may be referred to as light source light) from the light source is incident from the lower side of FIG. 22. In the top-gate structure of FIG. 22, since no light shielding member is present below the channel region 45 of the transistor, there is a possibility that the light source light is incident on the channel region 45 of the transistor in the non-light emitting region 6c. In the bottom-gate structure of FIG. 23, since the gate G is arranged below each transistor, the gate G can block the light source light, but there is a possibility that the light source light reach the channel region 45 through the periphery of the gate G.

As described above, in the first pixel region 6 having the non-light emitting region (transmissive window) 6c, there is a possibility that the natural light incident on the non-light emitting region (transmissive window) 6c reaches the channel region 45 of the transistor in the transmissive window in either a top-gate structure or a bottom-gate structure. Furthermore, in a case where the light source is arranged immediately below the non-light emitting region (transmissive window) 6c, there is a possibility that the light source light is incident on the channel region 45 of the transistor in either a top-gate structure or a bottom-gate structure.

As described above, when the natural light or the light source light is incident on the channel region 45 of the transistor, there is a possibility that the deterioration of the transistor (source-drain leakage due to light) is accelerated, and the display quality of the display panel 2 deteriorates accordingly.

Among the plurality of transistors in the pixel circuit 12 illustrated in FIGS. 7 to 21, there are a transistor that causes the deterioration in the display quality when the natural light or the light source light is incident, and a transistor that hardly affects the deterioration in the display quality. A transistor that should absolutely avoid incidence of the natural light and the light source light is the drive transistor Dr.

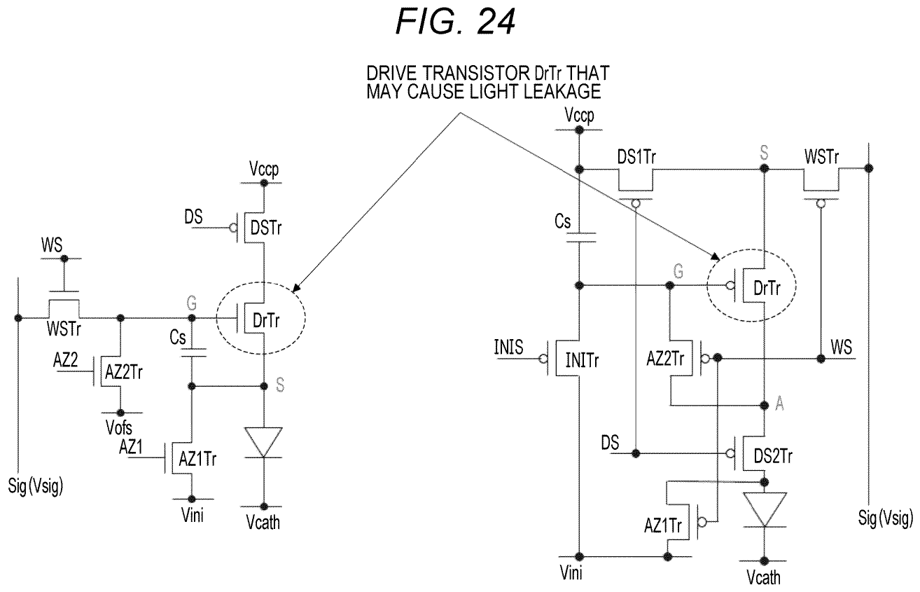

FIG. 24 is a diagram clearly indicating, with a broken line, the drive transistors Dr of the pixel circuits 12 of FIGS. 7 and 14. The drive transistor Dr control a current flowing through the OLED 20 by its gate voltage. When the natural light or the light source light is incident on the channel region 45 of the drive transistor Dr, the deterioration of the drive transistor Dr is accelerated, and for example, even if a predetermined gate voltage is applied, a desired drain-source current cannot flow. Therefore, the drive transistor Dr is a transistor having the highest priority in terms of the need of being shielded from the natural light and the light source light.

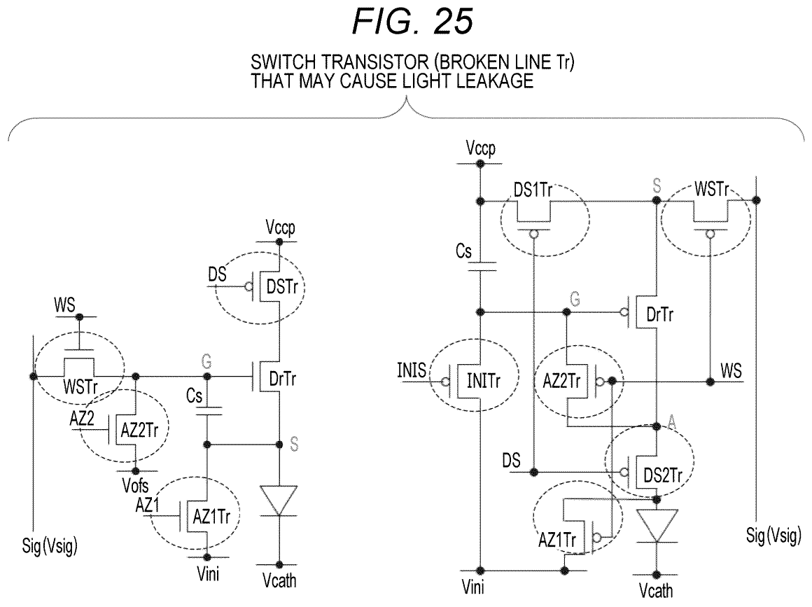

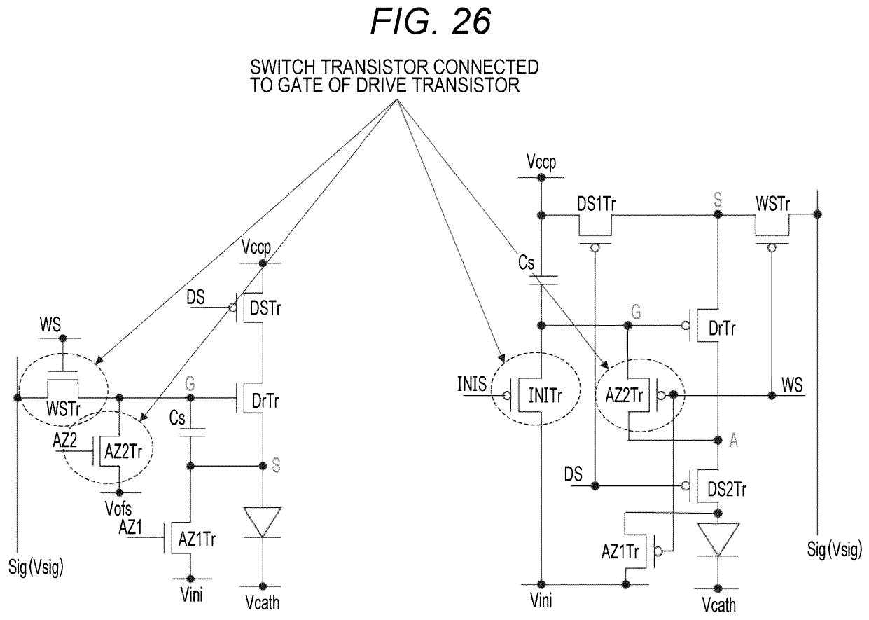

FIGS. 25 and 26 are diagrams clearly indicating, with a broken line, transistors having the second highest priority after the drive transistor Dr in terms of the need of being shielded from the natural light and the light source light. Such transistors are switch transistors that are directly connected to the drive transistor Dr or affect the voltage of the gate node of the drive transistor Dr. In the pixel circuit 12 of FIG. 7, the transistors correspond to the transistors WS, DS, AZ1, and AZ2. Furthermore, in the pixel circuit 12 of FIG. 14, the transistors correspond to the transistors WS, DS1, DS2, AZ1, AZ2, and INI.

In particular, as illustrated in FIG. 26, a transistor directly connected to the gate G of the drive transistor Dr is a transistor having the second highest priority after the drive transistor Dr in terms of the need of being shielded from light. Specifically, in the pixel circuit 12 of FIG. 7, the transistor corresponds to the transistors WS and AZ2, and, in the pixel circuit 12 of FIG. 14, the transistor corresponds to the transistors AZ2 and INI.

In the image display device 1 according to the present disclosure, a light shielding layer is provided in the vicinity of a transistor that affects the display quality in the non-light emitting region (transmissive window) 6c in the pixel circuit 12, and the natural light and the light source light are blocked from being incident on at least the channel region 45.

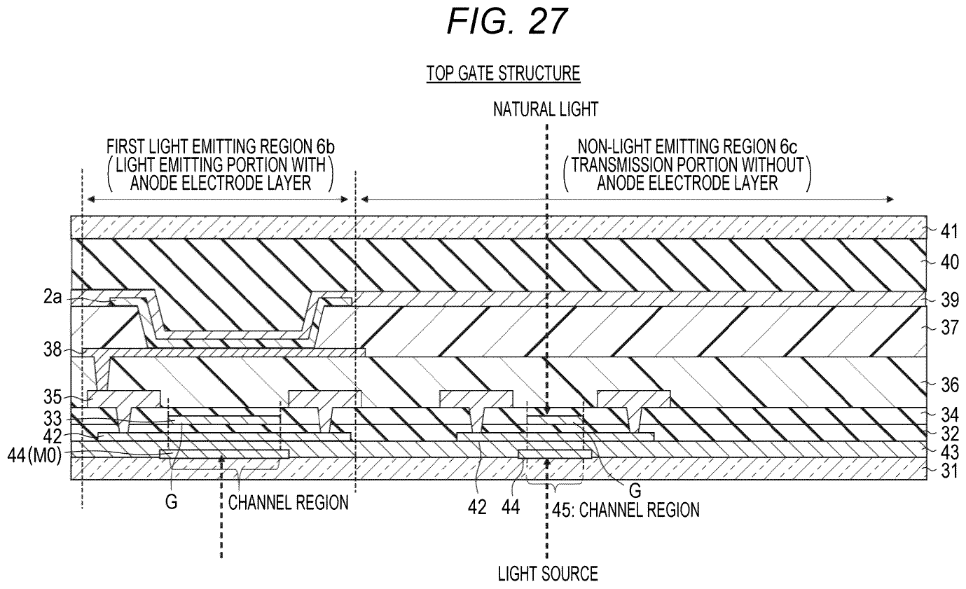

FIG. 27 is a cross-sectional view illustrating a first example of a light shielding layer 44. FIG. 27 illustrates an example in which the light shielding layer 44 is provided for the transistor having a top-gate structure. In FIG. 27, a 0-th wiring layer M0 is added below the first wiring layer (M1) 33, and the light shielding layer 44 is arranged in the 0-th wiring layer M0. Note that the 0-th wiring layer M0 is a name for convenience only, and may be referred to as a different name. The first wiring layer (M1) 33 is arranged on the first transparent substrate 31, and the periphery of the first wiring layer (M1) 33 is covered with the insulating layer 43. The layer configuration above the insulating layer 43 is similar to the layer configuration in FIG. 10, and the first insulating layer 32, the first wiring layer (M1) 33, the second insulating layer 34, the second wiring layer 35, the third insulating layer 36, the anode electrode layer 38, the fourth insulating layer 37, the display layer 2a, the cathode electrode layer 39, the fifth insulating layer 40, and the second transparent substrate 41 are sequentially layered.

The light shielding layer 44 is arranged so as to overlap with the channel region 45 of the transistor in the layering direction. The light shielding layer 44 may be arranged separately for each transistor to be shielded from light, or may have a size large enough to cover the channel regions 45 of the plurality of transistors to be shielded from light.

FIG. 27 illustrates an example in which the light shielding layer 44 corresponding to the transistor in the first light emitting region 6b in the first pixel region 6 and the light shielding layer 44 corresponding to the transistor in the non-light emitting region (transmissive window) 6c in the first pixel region 6 are separately provided. The transistor in the first light emitting region 6b is, for example, the drive transistor Dr. The transistor in the non-light emitting region 6c is a transistor, such as the transistors WS and DS, directly connected to the gate G, the source, or the like of the drive transistor Dr, or a transistor that affects the voltage of the gate node of the drive transistor Dr.

Since the pixel circuit 12 in FIG. 27 includes transistors having a top-gate structure, it is assumed that the natural light is shielded from light by the gate G of the transistor or the anode electrode layer 38. Therefore, no light shielding layer is provided above the gate G.

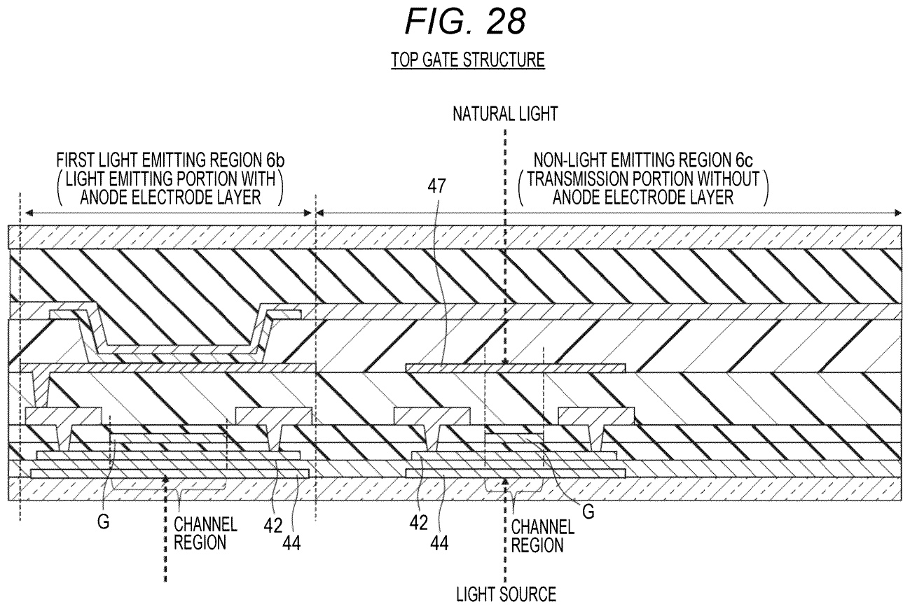

FIG. 28 is a cross-sectional view illustrating a second example of light shielding layers 44 and 47. The light shielding layer 44 in FIG. 28 is larger in area than the light shielding layer 44 in FIG. 27. Furthermore, the light shielding layer 47 is arranged above the gate G of the transistor in the non-light emitting region 6c in FIG. 28. The light shielding layer 47 above the gate G is arranged in the same layer as the anode electrode layer 38, for example.

In the second example, a case where the natural light or the light source light is incident from an oblique direction is taken into consideration. When the light shielding layer 44 is arranged in accordance with the size of the channel region 45 of the transistor, there is a possibility that the natural light or the light source light from an oblique direction is incident on the channel region 45 through a side of the light shielding layer 44. Therefore, in FIG. 28, the light shielding layer 44 larger in size than the channel region 45 of the transistor is provided to block oblique light.

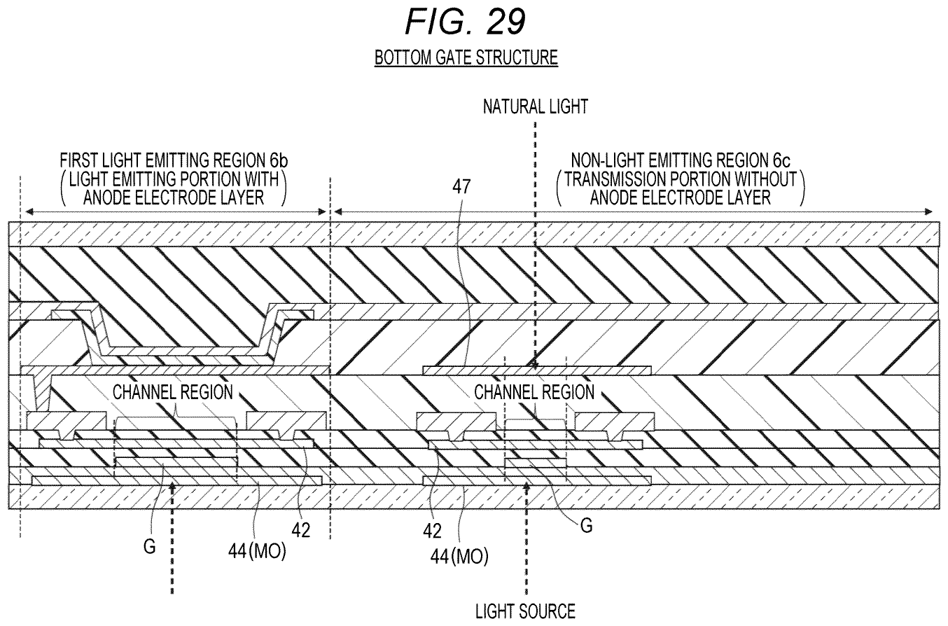

FIG. 29 is a cross-sectional view illustrating a third example of the light shielding layers 44 and 47. FIG. 29 illustrates an example in which the light shielding layers 44 and 47 are provided for a transistor having a bottom-gate structure. FIG. 29 is identical to FIGS. 27 and 28 in that the anode electrode layer 38 blocks the natural light without providing the light shielding layer 47 above the transistor in the first light emitting region 6b in the first pixel region 6. Since the gate G is not arranged above the channel region 45 of the transistor in the non-light emitting region (transmissive window) 6c, the light shielding layer 47 is essential. In FIG. 29, the light shielding layer 44 is arranged in the same layer as the anode electrode layer 38.

In a bottom-gate structure, the gate G is arranged below the channel region 45, and the channel region 45 can be shielded from the light source light only by the gate G. Taking oblique light into consideration, it is, however, desirable to arrange the light shielding layer 44 in the 0-th wiring layer M0 below the gate G as illustrated in FIG. 29. Furthermore, the light shielding layer 44 is desirably larger in size than the channel region 45.

The light shielding layer 44 illustrated in FIGS. 27 to 29 is desirably formed by a material that absorbs the natural light and the light source light. Examples of the material include tungsten and the like. FIG. 30 is a layout view of the pixel circuit 12 in a case where the light shielding layers 44 and 47 are provided for some transistors in the pixel circuit 12 of FIG. 7. The left side of FIG. 30 is a layout view of a side below the anode electrode layer 38, and the right side of FIG. 30 is a layout view in a state where the anode electrode layer 38 is arranged. FIG. 30 illustrates a bottom-gate structure in which the light shielding layer 44 is arranged below the channel region 45 of the drive transistor Dr and WS in the first light emitting region 6b, and the light shielding layer 47 is arranged above and below the channel region 45 of the transistors AZ2 and DS in the non-light emitting region 6c. In FIG. 30, measures against oblique light are taken by making the light shielding layers 44 and 47 larger in area than the channel region 45.

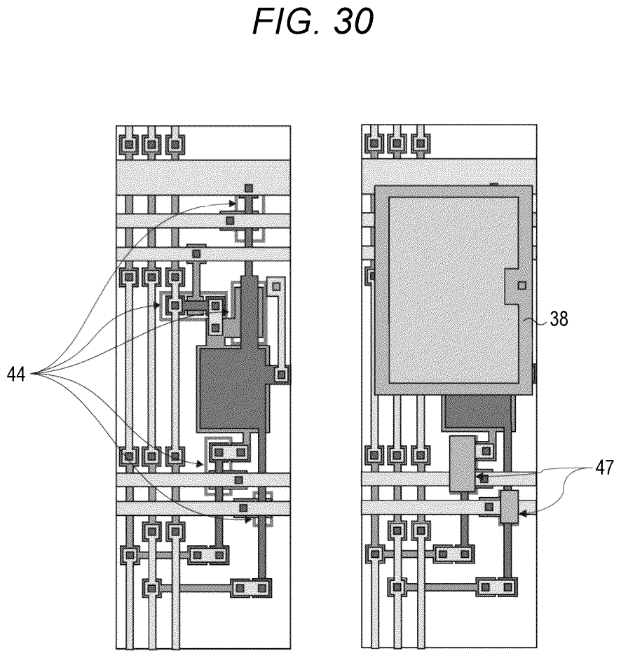

In FIG. 30, the light shielding layer 44 is arranged separately for each transistor to be shielded from light, but as illustrated in FIG. 31, a light shielding layer 47 having a size large enough to collectively cover a plurality of transistors located nearby may be arranged.

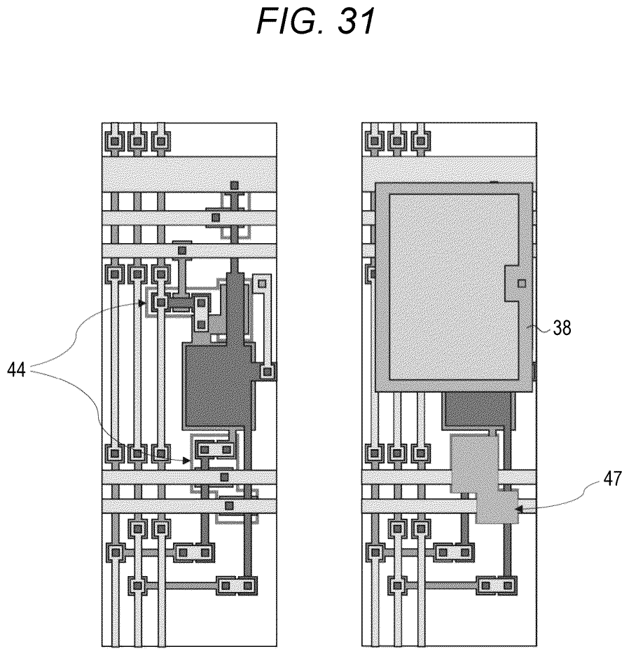

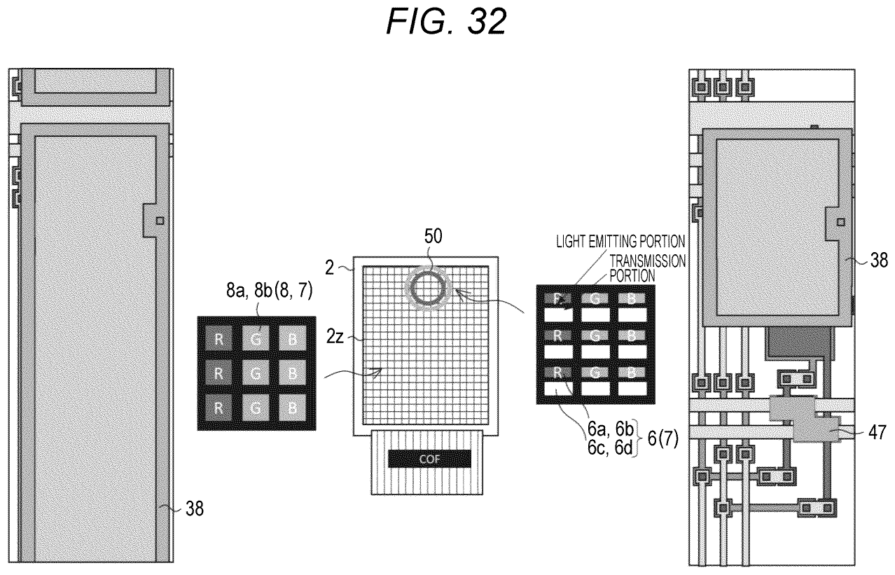

FIG. 32 is a view illustrating a pixel structure and a pixel layout of the first pixel region 6 and the second pixel region 8 in the display panel 2. The sensor 5 and the light source are arranged immediately below the display panel 2 in the first pixel region 6. The second pixel region 8 is a region where normal pixel display is performed, and neither the sensor 5 nor the light source is arranged immediately below the display panel 2.

In the first pixel region 6, the self light-emitting element (OLED 20) 6a, the first light emitting region 6b, and the non-light emitting region 6c having a transmissive window are provided, and the light shielding layers 44 and 47 are arranged for at least some transistors arranged in the non-light emitting region 6c. On the other hand, the second pixel region 8 is almost entirely covered with the anode electrode layer 38. Therefore, in the second pixel region 8, there is no possibility that the natural light is incident on the transistor. Furthermore, since no light source is arranged in the second pixel region 8, there is no possibility that the light source light is incident on the transistor.

FIG. 33 is a diagram illustrating a summary of arrangement locations of the light shielding layers 44 and 47 provided in the image display device 1 according to the present disclosure. The light shielding layers 44 and 47 are provided for shielding the transistors arranged in the non-light emitting region (transmissive window) 6c in the first pixel region 6 from the natural light and the light source light. Among the plurality of transistors in the pixel circuit 12, a transistor having the highest priority in terms of the need of arranging the light shielding layers 44 and 47 is the drive transistor Dr as described above. Since the drive transistor Dr controls the current flowing through the OLED 20 by its gate voltage, when the drive transistor Dr deteriorates, the current flowing through the OLED 20 changes even if a designed gate voltage is applied, luminance variations occur from pixel to pixel, and the display quality deteriorates accordingly. It is therefore essential to provide at least one of the light shielding layer 44 or the light shielding layer 47 for the drive transistor Dr.

Among the plurality of transistors in the pixel circuit 12, a transistor having the second highest priority after the drive transistor Dr in terms of the need of arranging the light shielding layers 44 and 47 differs in a manner that depends on the circuit configuration of the pixel circuit 12. As illustrated in FIG. 33, in the pixel circuit 12 of 5Tr1C of FIGS. 7 and 12, the transistors WS and AZ2 are the transistors having the second highest priority. In the pixel circuit 12 of 7Tr1C of FIG. 14, the transistors INI and AZ2 are the transistors having the second highest priority. In the pixel circuit 12 of 6Tr1C of FIG. 16, the transistors INI and AZ are the transistors having the second highest priority. In the pixel circuit 12 of 5Tr1C of FIG. 18 and the pixel circuit 12 of 4Tr1C of FIG. 20, the transistor AZ is the transistor having the second highest priority.

In a case of a transistor having a top-gate structure, it is essential to provide the light shielding layer 44 below the channel region 45. It is not essential to provide the light shielding layer 47 above the channel region 45, but, taking oblique light of the natural light into consideration, it is desirable to provide the light shielding layer 47 also above the channel region 45.

In a case of a transistor having a bottom-gate structure, it is essential to provide the light shielding layer 47 above the channel region 45. It is not essential to provide the light shielding layer 44 below the channel region 45, but, taking oblique light of the light source light into consideration, it is desirable to provide the light shielding layer 44 also below the channel region 45.

As described above, the transistors in the pixel circuit 12 are each formed by an NMOS transistor or a PMOS transistor, and each transistor has either a top-gate structure or a bottom-gate structure. Furthermore, in a case of an NMOS transistor, the LDD region is typically provided between the channel region 45 and the source/drain region. Providing the LDD region allows a relaxation of the electric field of the source/drain region and allows a reduction in off-leakage current. On the other hand, since the off-leakage is not a problem for a PMOS transistor, it is typical not to provide the LDD region. Furthermore, a plurality of combinations is also possible for the shapes and sizes of the light shielding layers 44 and 47. As described above, various combinations are possible for the cross-sectional structure of the pixel circuit 12. Hereinafter, representative variations of the cross-sectional structure and the planar layout of the non-light emitting region 6c in the first pixel region 6 will be sequentially described.

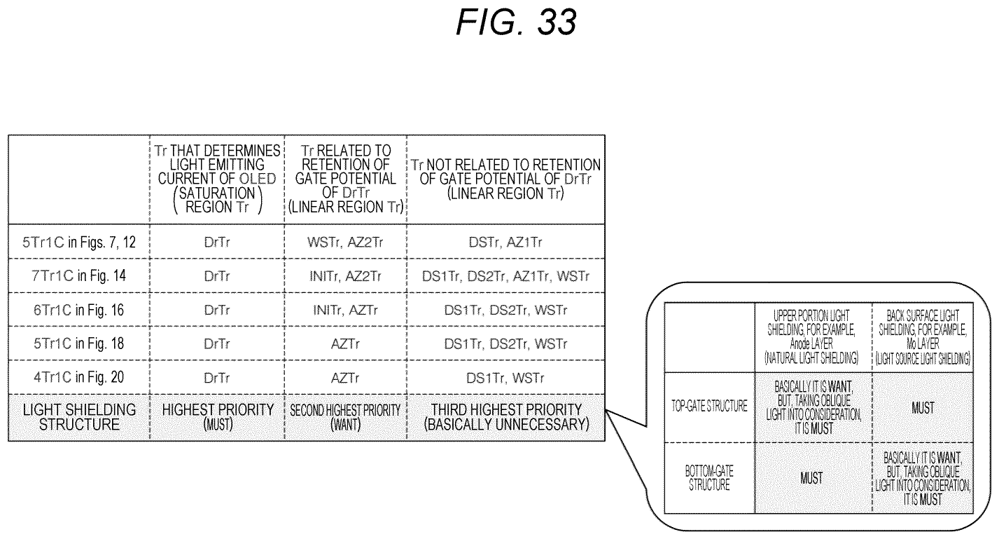

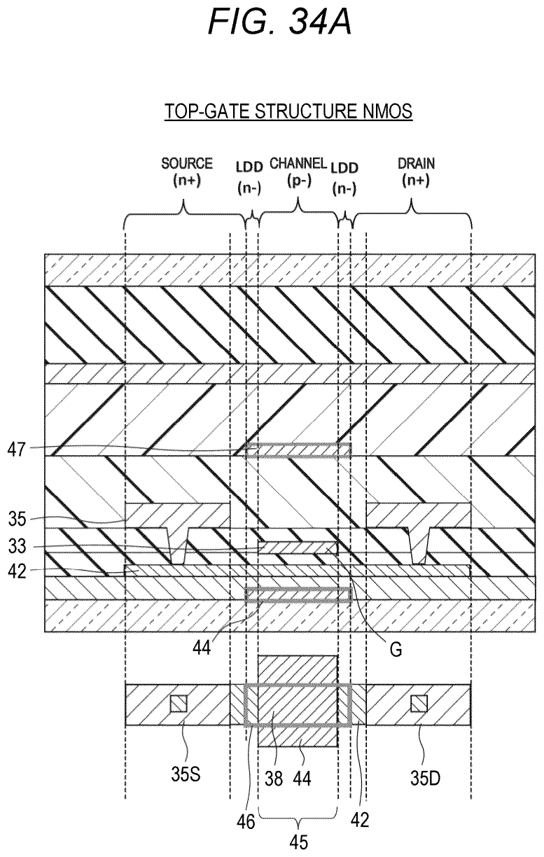

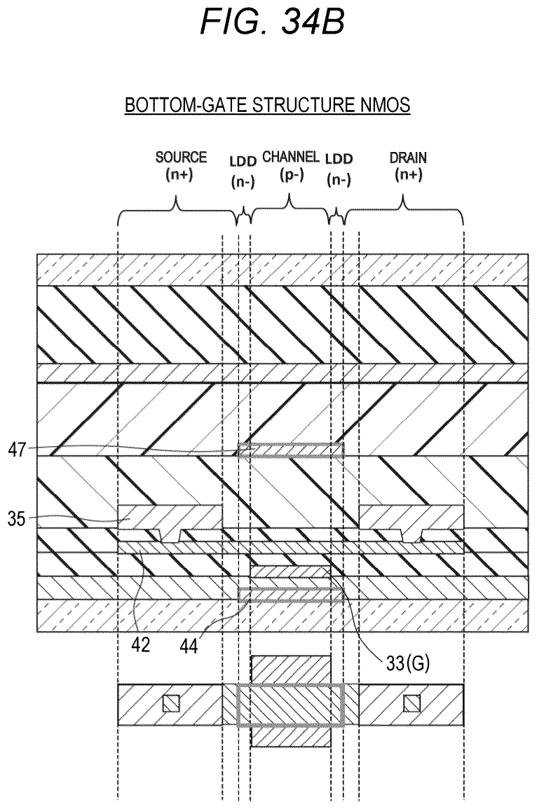

FIG. 34A is a view illustrating a cross-sectional structure and a planar layout of a non-light emitting region 6c according to a first example. FIG. 34A illustrates a cross-sectional structure and a planar layout of an NMOS transistor having a top-gate structure. An LDD region 46 is arranged between the channel region 45 and the source/drain region. The LDD region 46 is a region that is lower in impurity concentration than the source/drain region.

In the first example illustrated in FIG. 34A, the light shielding layer (hereinafter, referred to as a first light shielding layer) 47 is arranged above the gate G that is arranged in the first wiring layer (M1) 33. The first light shielding layer 47 has an area equal to or larger than the total area of the channel region 45 and the LDD region 46. Furthermore, the light shielding layer (hereinafter, referred to as a second light shielding layer) 44 is also arranged below the semiconductor layer 42 in which the channel region 45 and the LDD region 46 are formed. The second light shielding layer 44 also has an area equal to or larger than the total area of the channel region 45 and the LDD region 46.

As can be seen from FIG. 34A, uppermost layers (hereinafter, referred to as source electrode layer 35S/drain electrode layer 35D) of the source electrode connected to the source region and the drain electrode connected to the drain region extend in a plane direction and are arranged in the second wiring layer 35. The source electrode layer 35S, the light shielding layers 44 and 47, and the drain electrode layer 35D can block the natural light and oblique light of the natural light from being incident on the channel of the transistor.

FIG. 34B is a view illustrating a cross-sectional structure and a planar layout of a non-light emitting region 6c according to a second example. FIG. 3B illustrates a cross-sectional structure and a planar layout of an NMOS transistor having a bottom-gate structure. The LDD region 46 is arranged between the channel region 45 and the source/drain region. The light shielding layer (first light shielding layer) 47 is arranged above the channel region 45, and the light shielding layer (second light shielding layer) 44 is also arranged below the gate G. The first light shielding layer 47 and the second light shielding layer 44 each have an area equal to or larger than the total area of the channel region 45 and the LDD region 46.

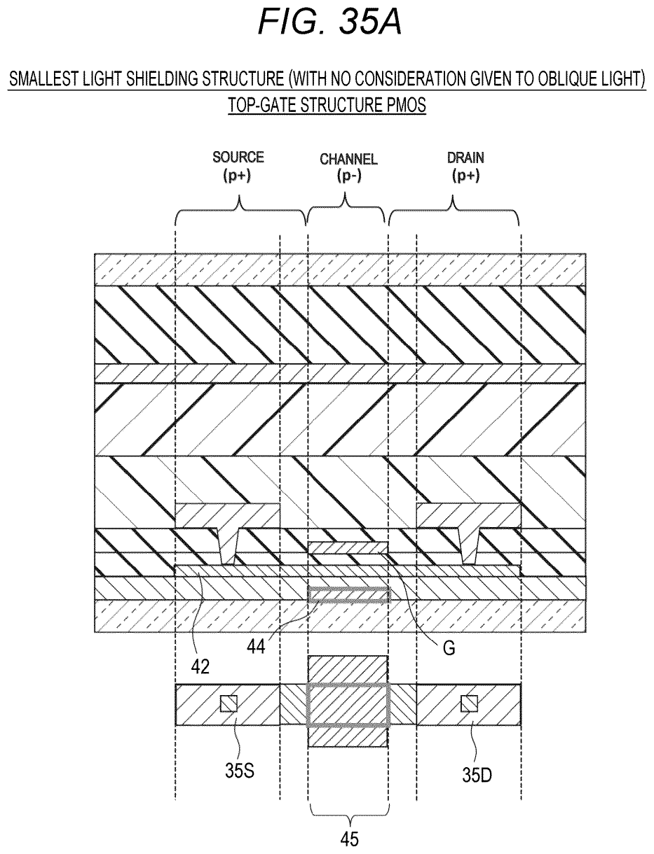

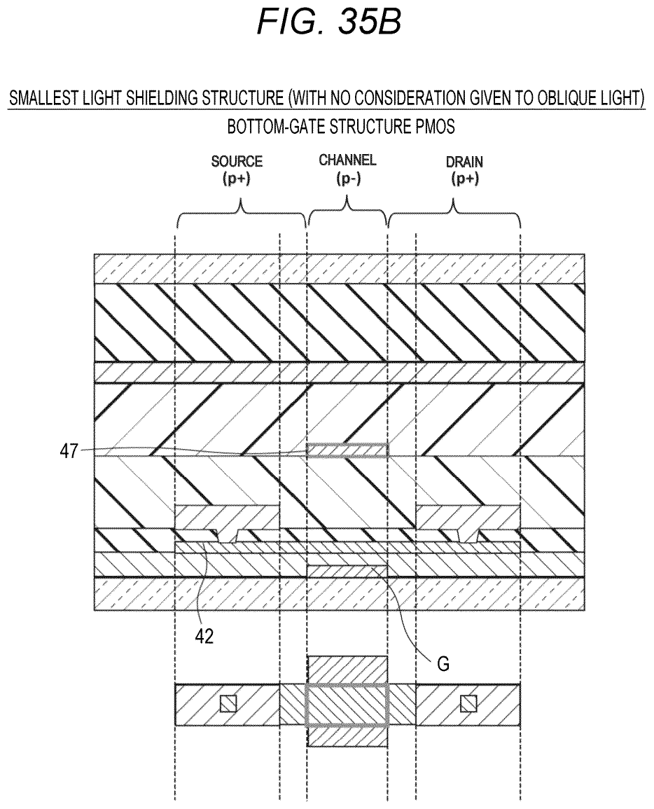

FIG. 35A is a view illustrating a cross-sectional structure and a planar layout of a non-light emitting region 6c according to a third example. FIG. 34A illustrates a cross-sectional structure and a planar layout of a PMOS transistor having a top-gate structure. Since it is a PMOS transistor, the LDD region 46 is not provided between the channel region 45 and the source/drain region. FIG. 35A illustrates an example in which the light shielding layer 44 has a minimum required size.

The gate G is arranged above the channel region 45 of the transistor, and the gate G can block the natural light, so that the light shielding layer 47 is not arranged above the gate G. Since the gate G is not arranged below the channel region 45, the light shielding layer 44 for blocking the light source light is arranged. The light shielding layer 44 has an area corresponding to the channel region 45. Unlike the NMOS transistor, the PMOS transistor has no LDD region 46, so that it is possible to further reduce the area of the light shielding layer 44.

FIG. 35B is a view illustrating a cross-sectional structure and a planar layout of a non-light emitting region 6c according to a fourth example. FIG. 35B illustrates a cross-sectional structure and a planar layout of a PMOS transistor having a bottom-gate structure. FIG. 35B illustrates an example in which the light shielding layer 44 has a minimum required size.

The light shielding layer (first light shielding layer) 47 is arranged above the channel region 45 of the transistor. The gate G is arranged below the channel region 45, and the gate G can block the light source light, so that the light shielding layer 44 is not arranged below the gate G.

In both FIGS. 35A and 35B, since the light shielding layers 44 and 47 each have the minimum required size, and oblique light of the natural light and oblique light of the light source light are not taken into consideration, there is a possibility that the deterioration of the transistor cannot be sufficiently suppressed.

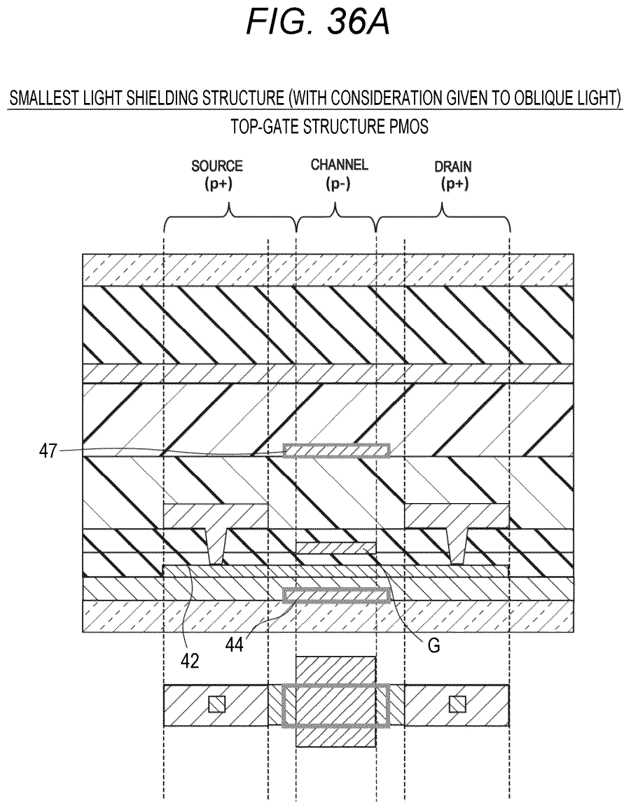

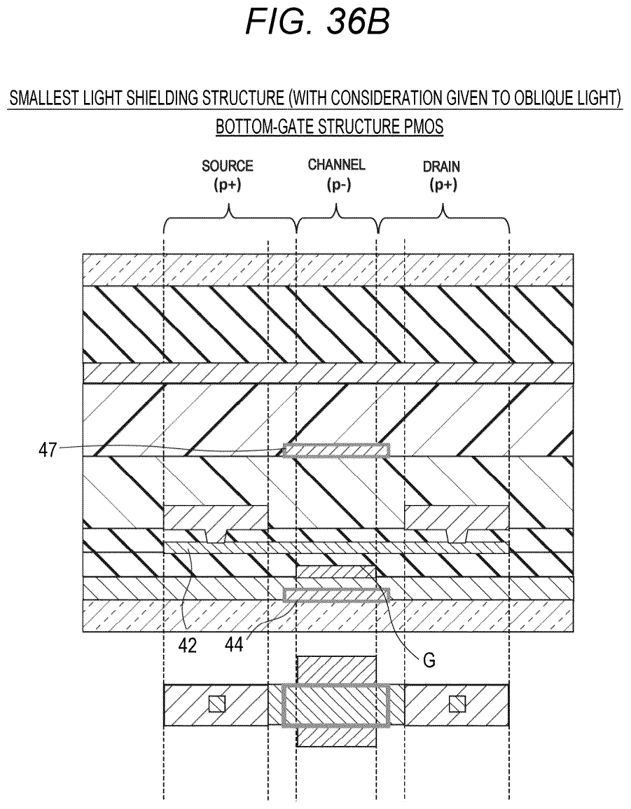

FIG. 36A is a view illustrating a cross-sectional structure and a planar layout of s non-light emitting region 6c according to a fifth example. FIG. 36A illustrates a cross-sectional structure and a planar layout of a PMOS transistor having a top-gate structure. Since it is a PMOS transistor, the LDD region 46 is not provided between the channel region 45 and the source/drain region. FIG. 36A illustrates an example in which the light shielding layers 44 and 47 are arranged in consideration of oblique light.

The gate G is arranged above the channel region 45 of the transistor, but the light shielding layer (first light shielding layer) 47 is arranged above the gate G in consideration of a possibility that oblique light of the natural light is incident on the channel region 45. The first light shielding layer 47 is larger in size than the gate G and the channel region 45 in consideration of oblique light. The light shielding layer (second light shielding layer) 44 is also arranged below the channel region 45, and the second light shielding layer 44 is made larger in size than the channel region 45 in consideration of oblique light of the light source light.

FIG. 36B is a view illustrating a cross-sectional structure and a planar layout of a non-light emitting region 6c according to a sixth example. FIG. 36B illustrates a cross-sectional structure and a planar layout of a PMOS transistor having a bottom-gate structure. FIG. 36B illustrates an example in which the light shielding layers 44 and 47 are arranged in consideration of oblique light.

The light shielding layer (first light shielding layer) 47 larger in size than the channel region 45 is arranged above the channel region 45 of the transistor. The gate G is arranged below the channel region 45, and the light shielding layer (second light shielding layer) 44 larger in size than the channel region 45 is arranged below the gate G.

In FIGS. 36A and 36B, it is necessary to change the sizes of the light shielding layers 44 and 47 in accordance with the angle of oblique light to be blocked. As the sizes of the light shielding layers 44 and 47 are made larger, it is possible to block oblique light in a wider angle range and to further suppress the deterioration of the transistor, but on the other hand, the aperture ratio of the transmissive window becomes lower. For this reason, there is a trade-off between the deterioration in the display quality caused by the deterioration of the transistor and the aperture ratio of the transmissive window.

In the first to sixth examples described above, there is a large gap between the source electrode layer 35S and the drain electrode layer 35D, and the gate G is arranged in the gap, but there is a possibility that oblique light of the natural light is incident on the channel region 45 or the LDD region 46 through the gap. Therefore, in various examples described below, at least one of the source electrode layer 35S or the drain electrode layer 35D is made larger in size to prevent the natural light from being incident on the channel region 45. As described above, at least one of the source electrode layer 35S or the drain electrode layer 35D can be used as a light shielding layer.

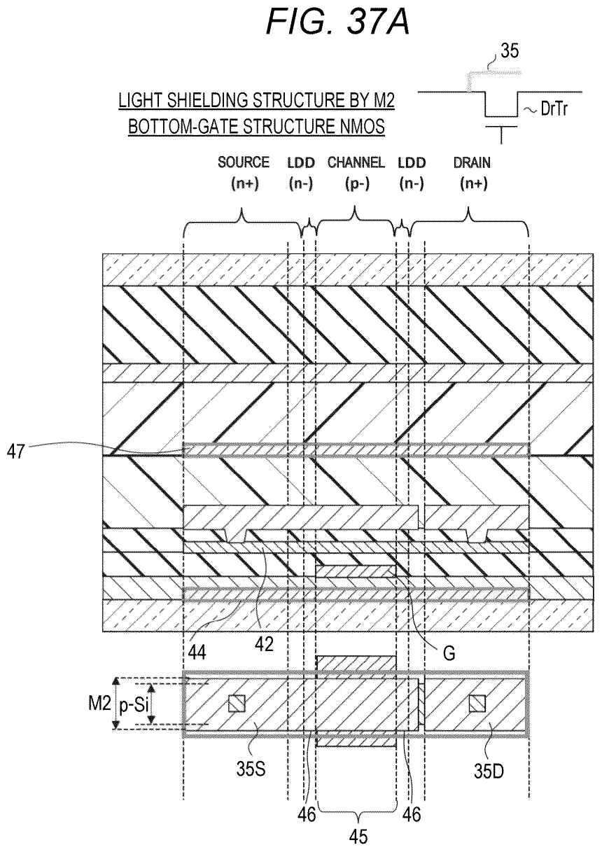

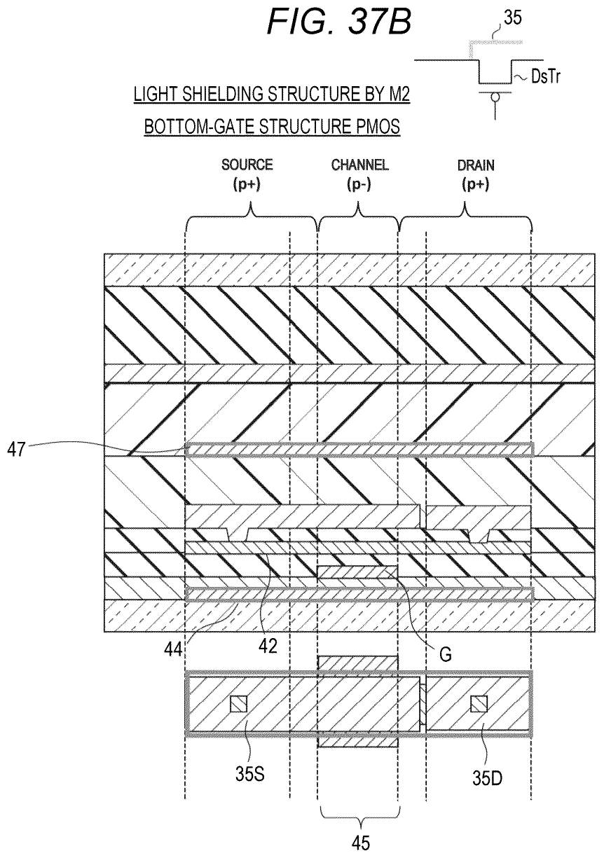

FIG. 37A is a view illustrating a cross-sectional structure and a planar layout of a non-light emitting region 6c according to a seventh example. FIG. 37A illustrates a cross-sectional structure and a planar layout of an NMOS transistor having a bottom-gate structure. The LDD region 46 is arranged between the channel region 45 and the source/drain region.

In FIG. 37A, the source electrode layer 35S and the drain electrode layer 35D are arranged in the second wiring layer 35, and the source electrode layer 35S is extended toward the drain electrode layer 35D so as to cover the channel region 45 from above. The transistor in FIG. 37A is a transistor such as the drive transistor Dr in which the direction of the current between the source and the drain does not change.

In the example in FIG. 37A, the light shielding layer (first light shielding layer) 47 is arranged above the source electrode layer 35S and the drain electrode layer 35D. The first light shielding layer 47 is arranged in the same layer as the anode electrode layer 38. Since the source electrode layer 35S shields the channel region 45 from light, the first light shielding layer 47 may be omitted. Furthermore, in a case where the first light shielding layer 47 is provided, the source electrode layer 35S may be made smaller in size.

FIG. 37B is a view illustrating a cross-sectional structure and a planar layout of a non-light emitting region 6c according to an eighth example. FIG. 37B illustrates a cross-sectional structure and a planar layout of a PMOS transistor having a bottom-gate structure. The LDD region 46 is not arranged between the channel region 45 and the source/drain region.

The eighth example is obtained by replacing the NMOS transistor in the seventh example with a PMOS transistor, and is almost identical in cross-sectional structure to the seventh example. Similarly to the seventh example, the source electrode layer 35S arranged in the second wiring layer extends toward the drain electrode layer 35D, and the light shielding layer (first light shielding layer) 47 is arranged above a source electrode device and the drain electrode layer 35D.

The seventh example in FIG. 37A and the eighth example in FIG. 37B include a transistor having a bottom-gate structure, but the transistor may be replaced with a transistor having a top-gate structure.

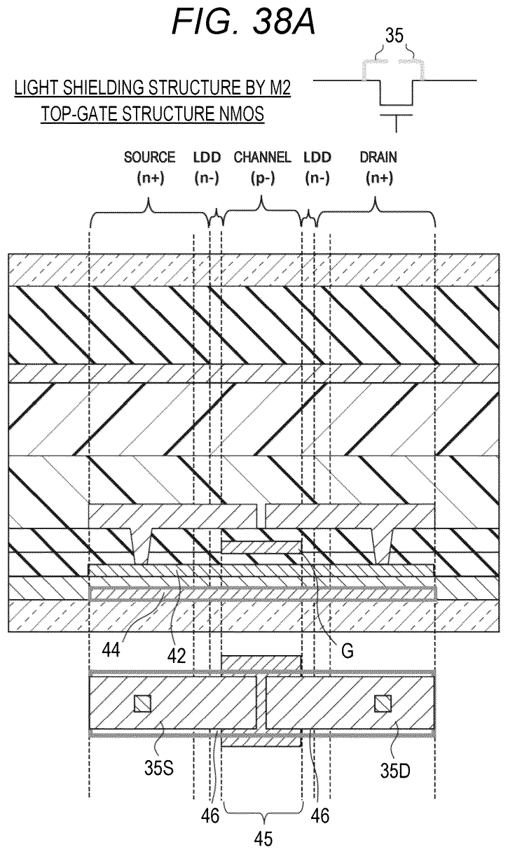

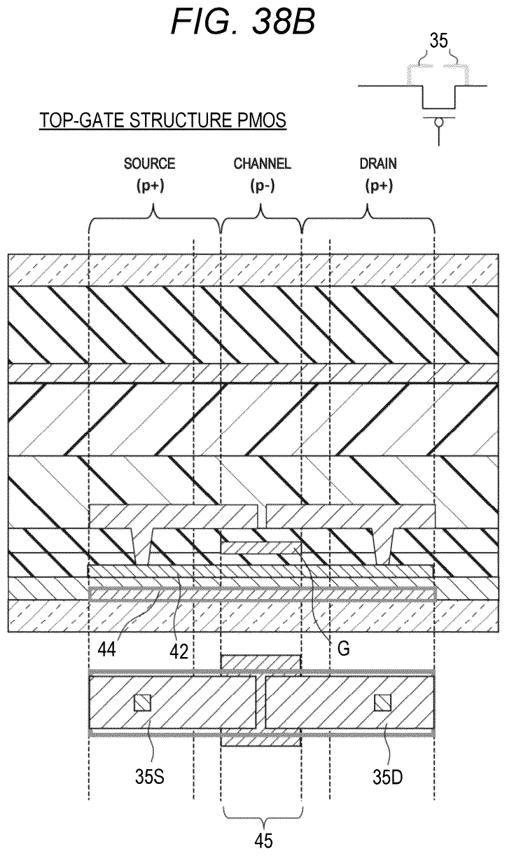

FIG. 38A is a view illustrating a cross-sectional structure and a planar layout of the non-light emitting region 6c according to the seventh example. FIG. 38A illustrates a cross-sectional structure and a planar layout of an NMOS transistor having a top-gate structure. The LDD region 46 is arranged between the channel region 45 and the source/drain region. The transistor in FIG. 38A is a transistor that performs an on or off switching operation (hereinafter, also referred to as a switch transistor) other than the drive transistor Dr. In the switch transistor, the roles of the source and the drain are not fixed, and the direction of the current between the source and the drain change in a manner that depends on circumstances. In this case, both the source electrode layer 35S and the drain electrode layer 35D are extended in the plane direction so as to arrange their respective distal end portions at a substantially central portion of the channel region 45.

As illustrated in FIG. 38A, the gate G is arranged above the channel region 45 of the transistor. The gate G is arranged in, for example, the first wiring layer (M1) 33. Above the gate G, the source electrode layer 35S and the drain electrode layer 35D are arranged so as to cover the channel region 45 and the LDD region 46.

As described above, in FIG. 38A, since the gate G, the source electrode layer 35S, and the drain electrode layer 35D shield the channel region 45 from light, the light shielding layer 47 need not be arranged above the source electrode layer 35S and the drain electrode layer 35D.

On the other hand, the light shielding layer (second light shielding layer) 44 is arranged below the channel region 45. The second light shielding layer 44 is larger in size than the channel region 45, and therefore can prevent the light source light and oblique light of the light source light from being incident on the channel region 45.

FIG. 38B is a view illustrating a cross-sectional structure and a planar layout of the non-light emitting region 6c according to the eighth example. FIG. 38B illustrates a cross-sectional structure and a planar layout of a PMOS transistor having a top-gate structure. The eighth example illustrated in FIG. 38B is different from the seventh example illustrated in FIG. 37B in the conductivity type of the transistor, and the LDD region 46 is not provided between the channel region 45 and the source/drain region. The eighth example, however, is similar in cross-sectional structure to the seventh example. The source electrode layer 35S and the drain electrode layer 35D are similarly extended to the vicinity of the center of the channel region 45.

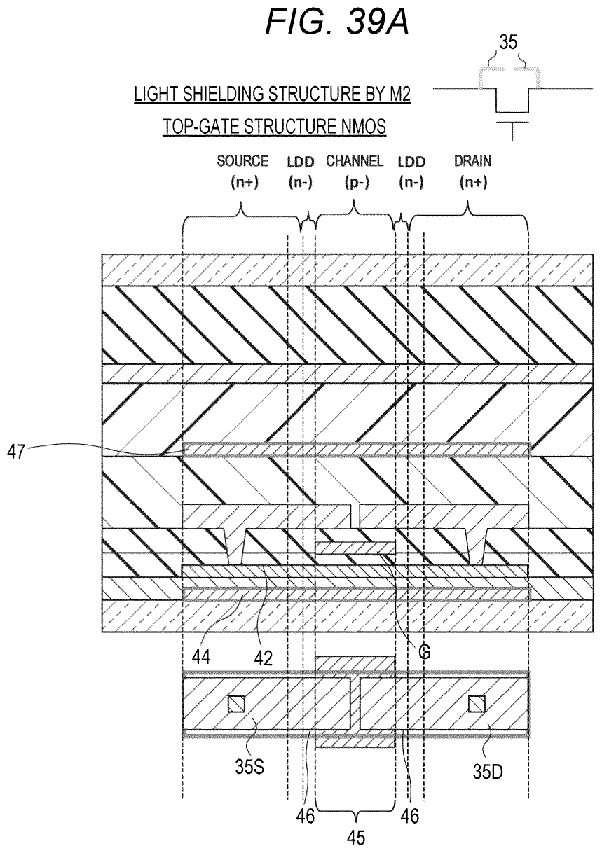

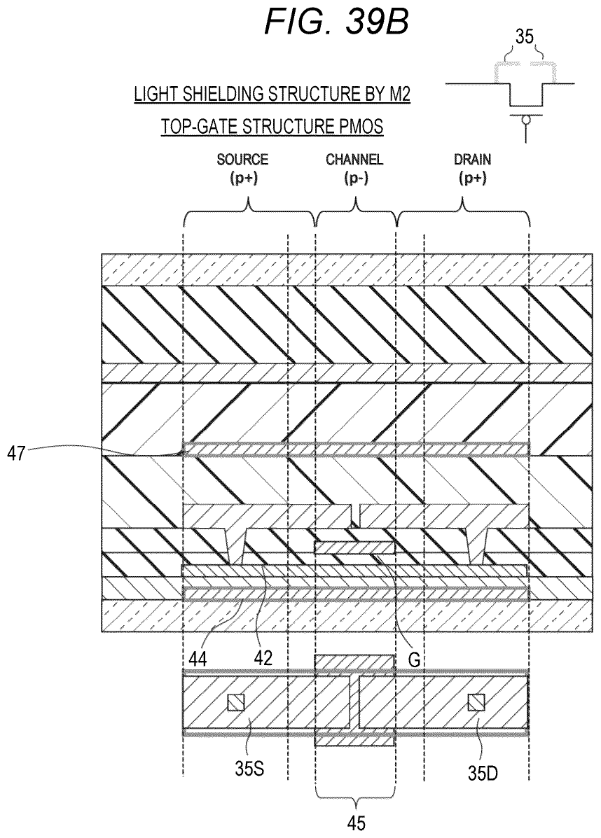

FIG. 39A is a view illustrating a cross-sectional structure and a planar layout of the non-light emitting region 6c according to a ninth example. FIG. 39A illustrates a cross-sectional structure and a planar layout of an NMOS transistor having a top-gate structure. The ninth example illustrated in FIG. 39A is obtained by arranging the light shielding layer (first light shielding layer) 47 above the source electrode layer 35S and the drain electrode layer 35D in the seventh example illustrated in FIG. 38A. Since it is a top-gate structure, the gate G is present above the channel region 45, the source electrode layer 35S and the drain electrode layer 35D are arranged above the gate G, and the first light shielding layer 47 is arranged above the source electrode layer 35S and the drain electrode layer 35D. It is therefore possible to prevent oblique light of the natural light from being incident on the channel region 45 more reliably.

FIG. 39B is a view illustrating a cross-sectional structure and a planar layout of the non-light emitting region 6c according to a tenth example. FIG. 39B illustrates a cross-sectional structure and a planar layout of a PMOS transistor having a top-gate structure. The tenth example illustrated in FIG. 39B is obtained by arranging the light shielding layer (first light shielding layer) 47 above the source electrode layer 35S and the drain electrode layer 35D in the eighth example illustrated in FIG. 38B, and produces an effect similar to the effect produced by the ninth example.

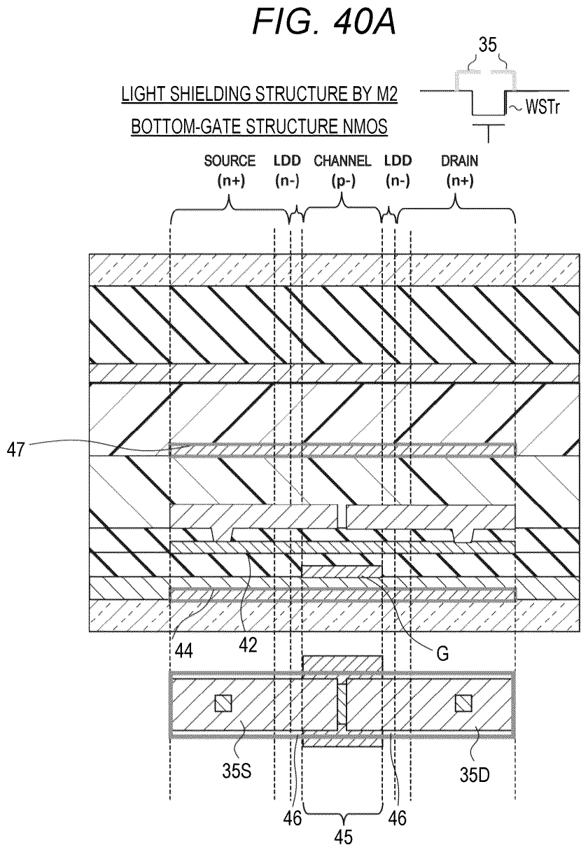

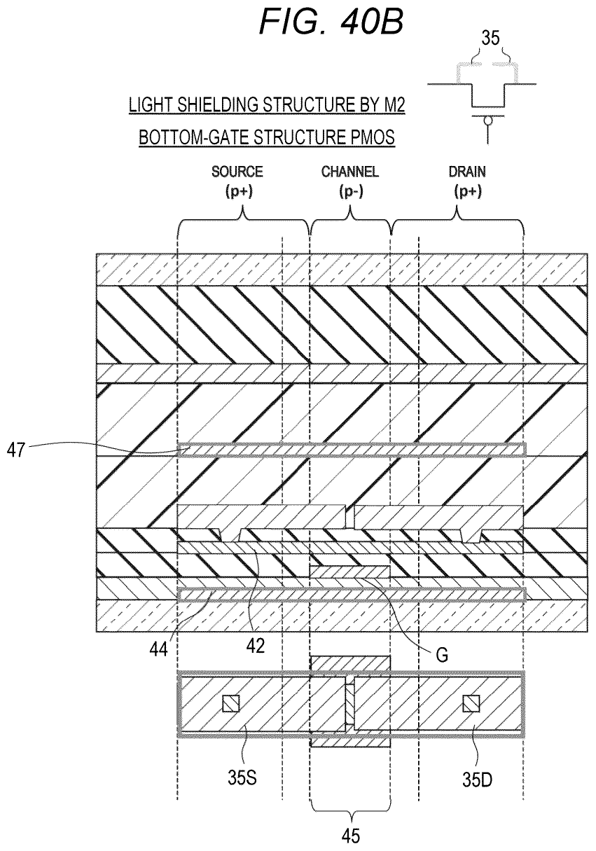

FIG. 40A is a view illustrating a cross-sectional structure and a planar layout of a non-light emitting region 6c according to an eleventh example. FIG. 40A illustrates a cross-sectional structure and a planar layout of an NMOS transistor having a bottom-gate structure. The LDD region 46 is arranged between the channel region 45 and the source/drain region. The transistor in FIG. 40A is a switch transistor that performs an on or off switching operation other than the drive transistor Dr.

In FIG. 40A, the gate G is arranged below the channel region 45 of the transistor. The gate G is arranged in, for example, the first wiring layer (M1) 33. Above the semiconductor layer 42 in which the channel region 45 is formed, the source electrode layer 35S and the drain electrode layer 35D are arranged so as to cover the channel region 45 and the LDD region 46. The source electrode layer 35S and the drain electrode layer 35D are arranged in, for example, the second wiring layer. The light shielding layer (first light shielding layer) 47 is arranged above the source electrode layer 35S and the drain electrode layer 35D.

In FIG. 40A, the channel region 45 and the LDD region 46 are shielded from light by the source electrode layer 35S, the drain electrode layer 35D, and the first light shielding layer 47. It is therefore possible to prevent oblique light of the natural light from being incident on the channel region 45.

FIG. 40B is a view illustrating a cross-sectional structure and a planar layout of a non-light emitting region 6c according to a twelfth example. FIG. 40B illustrates a cross-sectional structure and a planar layout of a PMOS transistor having a bottom-gate structure. The transistor in FIG. 40B is a switch transistor that performs an on or off switching operation other than the drive transistor Dr. FIG. 40B is identical in cross-sectional structure to FIG. 40A except that there is no LDD region 46.

In FIGS. 37A to 40B described above, at least one of the source electrode layer 35S or the drain electrode layer 35D is extended in the plane direction and used as a light shielding layer for the channel region 45 (and the LDD region 46). In the transistor (for example, the drive transistor Dr) in which the direction of the current flowing through the source and the drain is constant, the source electrode layer 35S is extended in the plane direction to cover the channel region 45. Furthermore, in the switch transistor, the source electrode layer 35S and the drain electrode layer 35D are extended in the plane direction to cover the channel region 45. As described above, not only providing the first light shielding layer 47 above the channel region 45 but also covering the channel region 45 with at least one of the source electrode layer 35S or the drain electrode layer 35D makes it possible to reliably prevent oblique light of the natural light from being incident on the channel region 45.

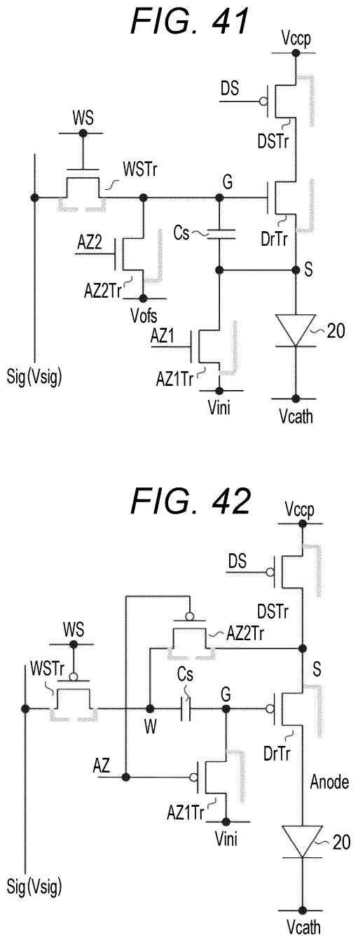

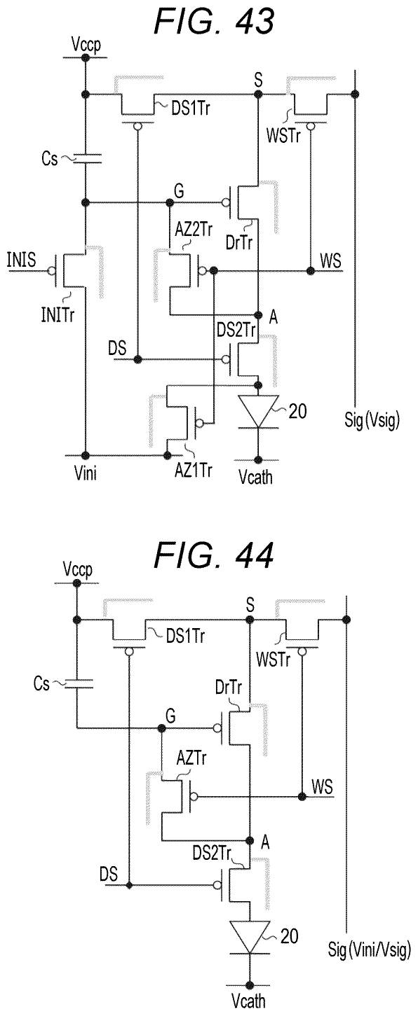

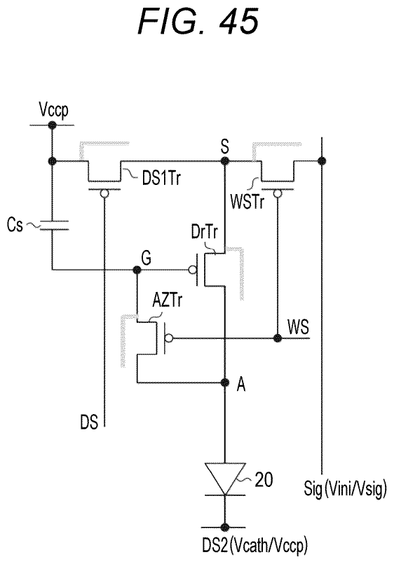

The transistor having the light shielding layer including at least one of the source electrode layer 35S or the drain electrode layer 35D illustrated in FIGS. 37A to 40B corresponds to at least some transistors in the pixel circuit 12. FIGS. 41 to 45 are circuit diagrams in which the above-described light shielding layer is provided in transistors in a plurality of pixel circuits 12 having different circuit configurations. FIG. 41 is a circuit diagram corresponding to the pixel circuit 12 of FIG. 7, FIG. 42 is a circuit diagram corresponding to the pixel circuit 12 of FIG. 12, FIG. 43 is a circuit diagram corresponding to the pixel circuit 12 of FIG. 14, FIG. 44 is a circuit diagram corresponding to the pixel circuit 12 of FIG. 18, and FIG. 45 is a circuit diagram corresponding to the pixel circuit 12 of FIG. 20.

As can be seen from the circuits of FIGS. 41 to 45, in some transistors in the pixel circuit 12, the source electrode layer 35S extends from the source side to cover the channel region 45. This type of transistor is a transistor in which the direction of the current flowing between the source and the drain is constant, and is, for example, the drive transistor Dr. Furthermore, in the other transistors in the pixel circuit 12, the source electrode layer 35S and the drain electrode layer 35D extend from the source side and the drain side to cover the channel region 45. This type of transistor is a transistor in which the roles of the source and the drain change according to circuit operation, and is, for example, the sampling transistor WS. Note that, depending on the configuration of the pixel circuit 12, the direction of the current flowing between the source and the drain of the sampling transistor becomes constant.

In order to prevent oblique light of the natural light and oblique light of the light source light from being incident on the channel region 45 of the transistor, it is desirable to use a contact region extending in the layering direction and arranged around the channel region 45 as a light shielding wall for blocking the oblique light. The contact region is provided to make the plurality of layers electrically continuous in the layering direction.

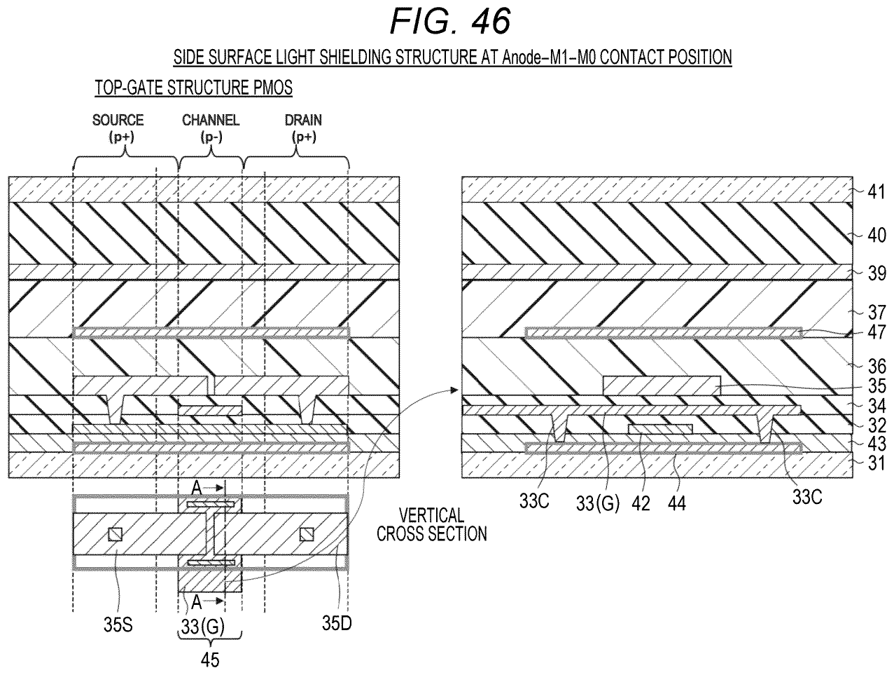

FIG. 46 is a view illustrating a cross-sectional structure and a planar layout of a non-light emitting region 6c according to a thirteenth example. FIG. 46 illustrates a cross-sectional structure and a planar layout of a PMOS transistor having a top-gate structure. A cross-sectional structure of the gate G in a direction of A-A line is illustrated on the right side of FIG. 46. As can be seen from the cross-sectional structure on the right side, a contact region 33 C extending in the layering direction is connected to the gate G, and the contact region 33C is connected to the light shielding layer (second light shielding layer) 44 arranged below the channel region 45. Therefore, the gate G and the second light shielding layer 44 are electrically continuous via the contact region 33C. Extending the contact region 33C in the depth direction of the paper surface allows the contact region 33C to be used as a light shielding wall that prevents oblique light of the natural light from being incident on the channel region 45.

The second light shielding layer 44 need not necessarily be electrically continuous with the gate G, and may be electrically continuous with another layer. Even in a case where electrical continuity is established with a layer other than the gate G, it is desirable to use the contact region 33C provided between the gate G and the layer as a light shielding wall.

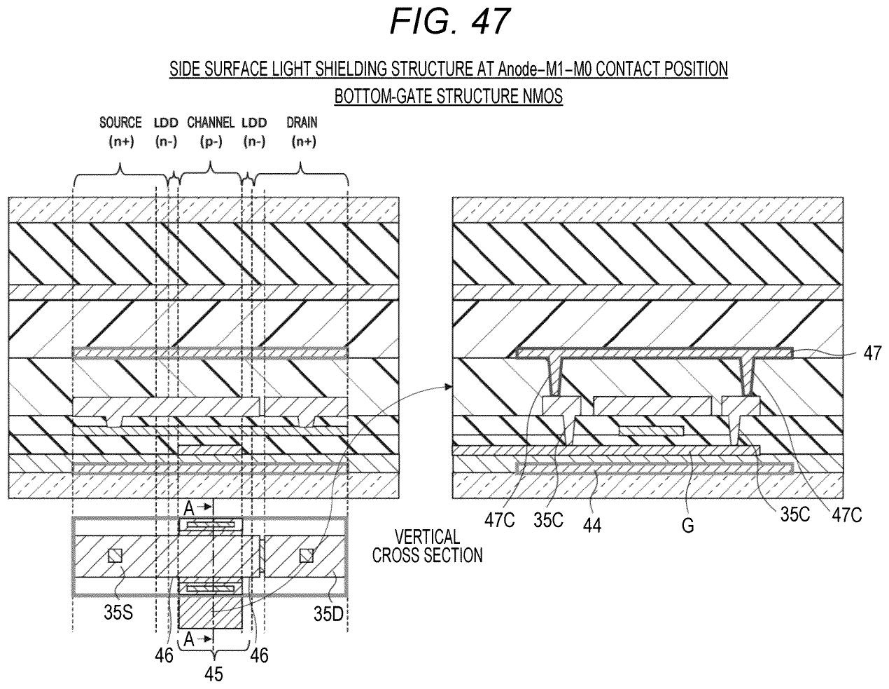

FIG. 47 is a view illustrating a cross-sectional structure and a planar layout of a non-light emitting region 6c according to a fourteenth example. FIG. 47 illustrates a cross-sectional structure and a planar layout of an NMOS transistor having a bottom-gate structure. The cross-sectional structure of the gate G in a direction of A-A line is illustrated on the right side of FIG. 47. In FIG. 47, the light shielding layer (first light shielding layer) 47 is arranged above the channel region 45 of the transistor, and the light shielding layer (second light shielding layer) 44 is arranged below the gate G that is arranged below the channel region 45. The first light shielding layer 47 is electrically continuous with the gate G via a first contact region 47C and a second contact region 35C extending in the layering direction. Extending the first contact region 47C and the second contact region 35C in the depth direction of the paper surface allows the first contact region 47C and the second contact region 35C to be used as a light shielding wall for the channel region 45.

As described above, the use of the image display device 1 according to the present disclosure makes it possible to solve the problem that, with the non-light emitting region (transmissive window) 6c provided in a part of the display panel 2, and the sensor and the light source arranged immediately below the non-light emitting region 6c, when the natural light or the light source light is incident on the transistor arranged in the non-light emitting region 6c, the deterioration of the transistor is accelerated, and the display quality deteriorates accordingly. Specifically, the light shielding layers 44 and 47 that shield the transistor in the non-light emitting region 6c from light are provided. Since the transistor deteriorates due to light incident on the channel region 45 of the transistor, the light shielding layers 44 and 47 are provided at places where light can be prevented from being incident on the channel region 45. It is possible to reliably prevent, by making the areas of the light shielding layers 44 and 47 equal to or larger than the area of the channel region 45, oblique light of the natural light or oblique light of the light source light from being incident on the channel region 45.

The pixel circuit 12 includes a plurality of transistors, but it is not necessary to arrange the light shielding layers 44 and 47 for all the transistors in the pixel circuit 12. Since the drive transistor Dr in the pixel circuit 12 controls the current flowing through the OLED 20, it is necessary to provide the light shielding layers 44 and 47 for the drive transistor Dr. In addition, it is desirable to provide the light shielding layers 44 and 47 also for a transistor that affects the voltage of the gate node of the drive transistor Dr. Furthermore, it is desirable to provide the light shielding layers 44 and 47 also for a transistor connected to the source or the drain of the drive transistor Dr.

In a case where the transistors in the pixel circuit 12 are NMOS transistors, the LDD region 46 is provided between the channel region 45 and the source/drain region. In this case, not only the channel region 45 but also the LDD region 46 are desirably shielded from light by the light shielding layers 44 and 47.

Each transistor in the pixel circuit 12 has a top-gate structure or a bottom-gate structure. In either structure, the light shielding layers 44 and 47 can be arranged by using at least one layer of the 0-th wiring layer M0, the first wiring layer (M1) 33, the second wiring layer, or the anode electrode layer 38. More specifically, in a top-gate structure, since the gate G is arranged on the channel region 45, it is not essential to arrange the light shielding layer (first light shielding layer) 47 on the gate G, but, taking oblique light into consideration, it is desirable to arrange the first light shielding layer 47. In a top-gate structure, since the gate G is not arranged below the channel region 45, it is necessary to provide the light shielding layer (second light shielding layer) 44 below the channel region 45. In a bottom-gate structure, since the gate G is not arranged above the channel region 45, it is necessary to arrange the light shielding layer (first light shielding layer) 47 above the channel region 45. In a bottom-gate structure, since the gate G is arranged below the channel region 45, it is not essential to arrange the light shielding layer (second light shielding layer) 44 below the gate G, but, taking oblique light into consideration, it is desirable to arrange the second light shielding layer 44.

At least one of the source electrode layer 35S or the drain electrode layer 35D may be extended in the plane direction to cover the channel region 45. Measures against oblique light of the natural light can be taken by not only arranging the light shielding layer (first light shielding layer) 47 above the channel region 45 but also covering the channel region 45 with at least one of the source electrode layer 35S or the drain electrode layer 35D.

### Application Example of Image Display Device 1 and Electronic Device 50 According to Present Disclosure

### First Application Example

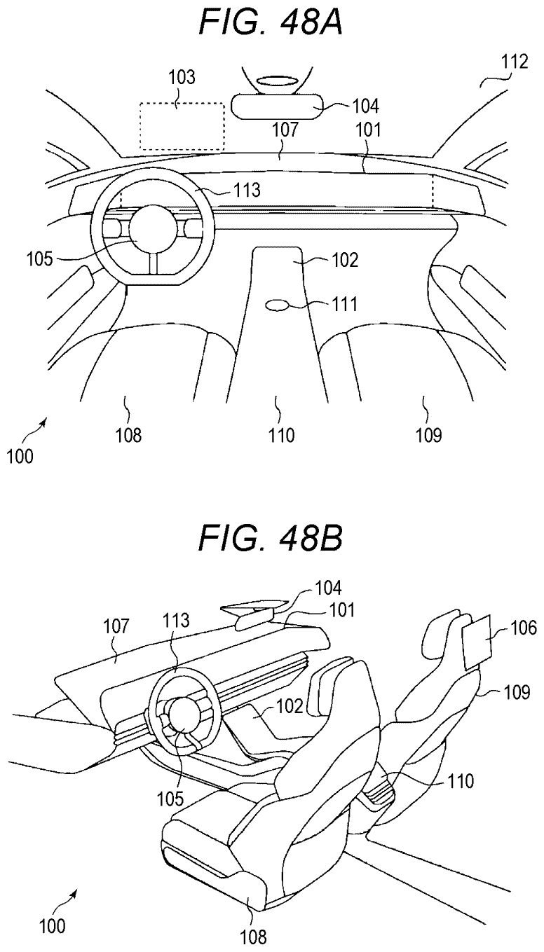

The image display device 1 and the electronic device 50 according to the present disclosure can be used for various purposes. FIGS. 48A and 48B are views illustrating an internal configuration of a vehicle 100 as a first application example of the electronic device 50 including the image display device 1 according to the present disclosure. FIG. 48A is a view illustrating an internal state of the vehicle 100 from a rear side to a front side of the vehicle 100, and FIG. 48B is a view illustrating an internal state of the vehicle 100 from an oblique rear side to an oblique front side of the vehicle 100.

The vehicle 100 of FIGS. 48A and 48B includes a center display 101, a console display 102, a head-up display 103, a digital rear mirror 104, a steering wheel display 105, and a rear entertainment display 106.

The center display 101 is arranged on a dashboard 107 at a location facing a driver seat 108 and a passenger seat 109. FIG. 48 illustrates an example of the center display 101 having a horizontally long shape extending from the driver seat 108 side to the passenger seat 109 side, but any screen size and arrangement location of the center display 101 may be adopted. The center display 101 can display information detected by the various sensors 5. As a specific example, the center display 101 can display a captured image captured by an image sensor, and an image of a distance to an obstacle in front of or on the side of the vehicle measured by a time of flight (ToF) sensor 5, a passenger's body temperature detected by an infrared sensor 5, and the like. The center display 101 can be used to display, for example, at least one of safety-related information, operation-related information, a life log, health-related information, authentication/identification-related information, or entertainment-related information.

The safety-related information is information of doze detection, looking-aside detection, detection of a child passenger getting into mischief, wearing or not wearing of a seat belt, detection of leaving of an occupant behind, and the like, and is information detected by the sensor 5 arranged, for example, to overlap with the back surface side of the center display 101. The operation-related information is a gesture related to an operation by the occupant detected by using the sensor 5. The detected gesture may include an operation of various types of equipment in the vehicle 100. For example, operations of air conditioning equipment, a navigation device, an audio and visual (AV) device, a lighting device, and the like are detected. The life log includes life logs of all the occupants. For example, the life log includes an action record of each occupant in the vehicle. By acquiring and storing the life log, it is possible to check a state of the occupant at the time of an accident. In the health-related information, the health condition of the occupant is estimated on the basis of the body temperature of the occupant detected by using a temperature sensor 5. Alternatively, the face of the occupant may be captured by using the image sensor and the health condition of the occupant may be estimated from the captured facial expression of the occupant. Moreover, a conversation using the automatic voice may be made with the occupant, and the health condition of the occupant may be estimated on the basis of the content of the answer from the occupant. The authentication/identification-related information includes a keyless entry function of performing face authentication by using the sensor 5, a function of automatically adjusting a seat height and position by face identification, and the like. The entertainment-related information includes a function of detecting operation information of the AV device by the occupant by using the sensor 5, a function of recognizing the face of the occupant by the sensor 5 and providing a content suitable for the occupant by the AV device, and the like.

The console display 102 can be used, for example, to display the life log information. The console display 102 is arranged near a shift lever 111 of a center console 110 between the driver seat 108 and the passenger seat 109. The console display 102 can also display information detected by the various sensors 5. Furthermore, the console display 102 may display an image of the vehicle surroundings captured by the image sensor, or may display an image of a distance to an obstacle in the vehicle surroundings.

The head-up display 103 is virtually displayed behind a windshield 112 in front of the driver seat 108. The head-up display 103 can be used to display, for example, at least one of the safety-related information, the operation-related information, the life log, the health-related information, the authentication/identification-related information, or the entertainment-related information. Because the head-up display 103 is virtually arranged in front of the driver seat 108 in many cases, the head-up display 103 is suitable for displaying information directly related to an operation of the vehicle 100, such as a speed of the vehicle 100 and a remaining amount of fuel (battery).

The digital rear mirror 104 can not only display the rear side of the vehicle 100 but also a state of the occupant in the rear seat, and thus can be used to display, for example, the life log information by arranging the sensor 5 to overlap with the back surface side of the digital rear mirror 104.

The steering wheel display 105 is arranged near the center of a steering wheel 113 of the vehicle 100. The steering wheel display 105 can be used to display, for example, at least one of the safety-related information, the operation-related information, the life log, the health-related information, the authentication/identification-related information, or the entertainment-related information. In particular, because the steering wheel display 105 is close to the driver's hand, the steering wheel display 105 is suitable for displaying the life log information such as a body temperature of the driver, or for displaying information associated with an operation of the AV device, air conditioning equipment, or the like.

The rear entertainment display 106 is attached to the back side of the driver seat 108 and the passenger seat 109, and is for viewing by the occupant in the rear seat. The rear entertainment display 106 can be used to display, for example, at least one of the safety-related information, the operation-related information, the life log, the health-related information, the authentication/identification-related information, or the entertainment-related information. In particular, because the rear entertainment display 106 is in front of the occupant in the rear seat, information related to the occupant in the rear seat is displayed. For example, information associated with the operation of the AV device or the air conditioning equipment may be displayed, or a result of measuring the body temperature or the like of the occupant in the rear seat by the temperature sensor 5 may be displayed.

As described above, by arranging the sensor 5 to overlap with the back surface side of the image display device 1, a distance to an object that is present the surroundings can be measured. Optical distance measurement methods are roughly classified into a passive type and an active type. In the passive type method, a distance is measured by receiving light from the object without projecting light from the sensor 5 to the object. The passive type method includes a lens focus method, a stereo method, a monocular vision method, and the like. In the active type method, a distance is measured by projecting light onto the object and receiving reflected light from the object with the sensor 5. The active type method includes an optical radar method, an active stereo method, an illuminance difference stereo method, a moire topography method, an interference method, and the like. The image display device 1 according to the present disclosure can be applied to any of these types of distance measurement. By using the sensor 5 arranged to overlap with the back surface side of the image display device 1 according to the present disclosure, the distance measurement of the passive type or the active type described above can be performed.

### Second Application Example

The image display device 1 according to the present disclosure is applicable not only to various displays used in vehicles but also to displays mounted on various electronic devices 50.

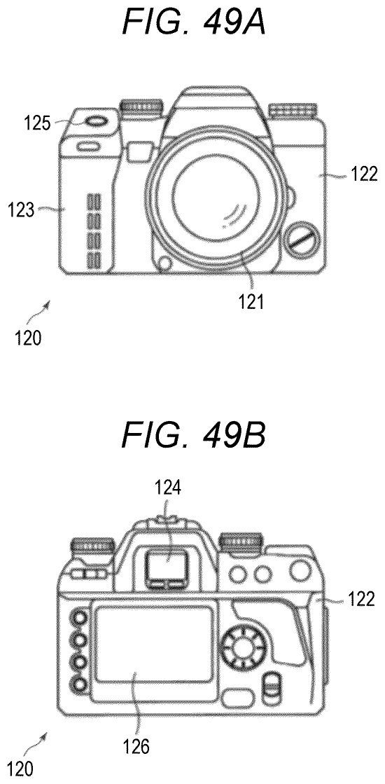

FIG. 49A is a front view of a digital camera 120 as a second application example of the electronic device 50, and FIG. 49B is a rear view of the digital camera 120. The digital camera 120 of FIGS. 49A and 49B illustrates an example of a single-lens reflex camera in which a lens 121 is replaceable, but the display device 1 is also applicable to a camera in which the lens 121 is not replaceable.

In the camera of FIGS. 49A and 49B, when a person who captures an image looks into an electronic viewfinder 124 to determine a composition while holding a grip 123 of a camera body 122, and presses a shutter 125 while adjusting focus, image-capturing data is stored in a memory in the camera. As illustrated in FIG. 49B, on a back side of the camera, a monitor screen 126 that displays captured data and the like and a live image and the like, and the electronic viewfinder 124 are provided. Furthermore, there is a case where a sub screen that displays setting information such as a shutter speed and an exposure value is provided on the upper surface of the camera.

By arranging the sensor 5 so as to overlap with the back surface side of the monitor screen 126, the electronic viewfinder 124, the sub screen, and the like used for the camera, the camera can be used as the image display device 1 according to the present disclosure.

### Third Application Example

The image display device 1 according to the present disclosure is also applicable to a head mounted display (hereinafter, referred to as an HMD). The HMD can be used for virtual reality (VR), augmented reality (AR), mixed reality (MR), substitutional reality (SR), or the like.

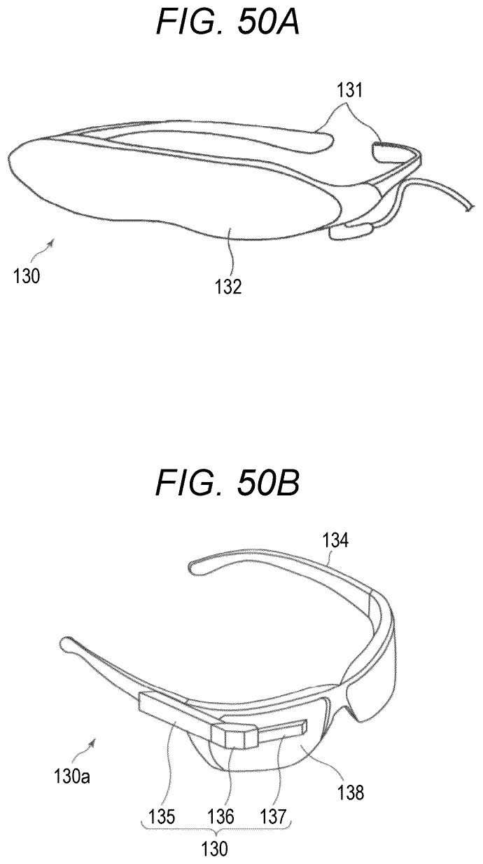

FIG. 50A is an external view of an HMD 130 as a third application example of the electronic device 50. The HMD 130 of FIG. 50A includes a mounting member 131 for attachment to cover human eyes. The mounting member 131 is, for example, hooked and fixed to human ears. A display device 132 is provided inside the HMD 130, and a wearer of the HMD 130 can visually recognize a stereoscopic image and the like with the display device 132. The HMD 130 includes, for example, a wireless communication function, an acceleration sensor, and the like, and can switch a stereoscopic image and the like displayed on the display device 132 in accordance with a posture, a gesture, and the like of the wearer.

Furthermore, a camera may be provided in the HMD 130 to capture an image around the wearer, and an image obtained by combining the captured image of the camera and an image generated by a computer may be displayed on the display device 132. For example, by arranging the camera to overlap with the back surface side of the display device 132 visually recognized by the wearer of the HMD 130, capturing an image of the surroundings of the eyes of the wearer with the camera, and displaying the captured image on another display provided on the outer surface of the HMD 130, a person around the wearer can grasp expression of the face and a movement of the eyes of the wearer in real time.

Note that various types of the HMD 130 are conceivable. For example, as illustrated in FIG. 50B, the image display device 1 according to the present disclosure can also be applied to a smart glass 130a that displays various types of information on glasses 134. The smart glass 130a of FIG. 50B includes a main body portion 135, an arm portion 136, and a lens barrel portion 137. The main body portion 135 is connected to the arm portion 136. The main body portion 135 is detachable from the glasses 134. The main body portion 135 incorporates a display unit and a control board for controlling an operation of the smart glass 130a. The main body portion 135 and the lens barrel are connected to each other via the arm portion 136. The lens barrel portion 137 emits image light emitted from the main body portion 135 through the arm portion 136, to the lens 138 side of the glasses 134. This image light enters the human eyes through the lens 138. A wearer of the smart glass 130a of FIG. 50B can visually recognize not only a surrounding situation but also various pieces of information emitted from the lens barrel portion 137 similarly to normal glasses.

### Fourth Application Example

The image display device 1 according to the present disclosure is also applicable to a television device (hereinafter, a TV). In recent TVs, a frame tends to be as small as possible from the viewpoint of downsizing and design properties. Therefore, in a case where a camera to capture an image of a viewer is provided on a TV, it is desirable to arrange the camera so as to overlap with the back surface side of a display panel 2 of the TV.

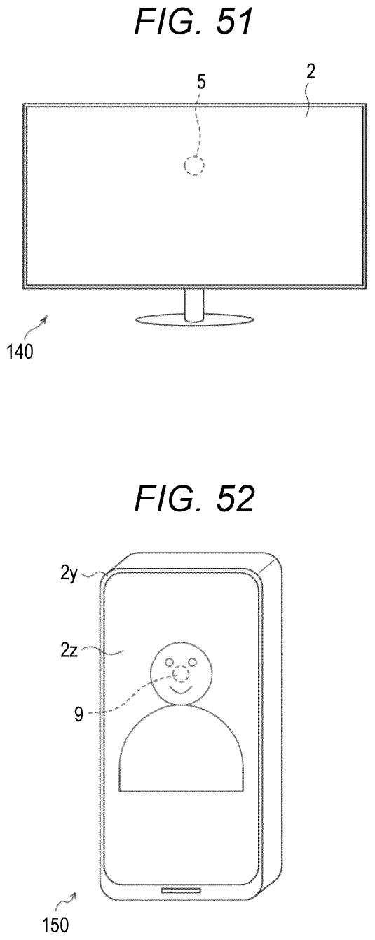

FIG. 51 is an external view of a TV 140 as a fourth application example of the electronic device 50. In the TV 140 of FIG. 51, the frame is minimized, and almost the entire region on the front side is a display area. The TV 140 incorporates a sensor 5 such as a camera to capture the image of the viewer. The sensor 5 in FIG. 51 is arranged on the back side of a part (for example, a broken line part) in the display panel 2. The sensor 5 may be an image sensor module, or various sensors can be applied such as a sensor for face authentication, a sensor for distance measurement, and a temperature sensor, and a plurality of types of sensors may be arranged on the back surface side of the display panel 2 of the TV 140.

As described above, according to the image display device 1 of the present disclosure, the image sensor module 9 can be arranged to overlap with the back surface side of the display panel 2. Therefore, there is no need to arrange a camera or the like on the frame, the TV 140 can be downsized, and there is no possibility that the design is impaired by the frame.

### Fifth Application Example

The image display device 1 according to the present disclosure is also applicable to a smartphone and a mobile phone. FIG. 52 is an external view of a smartphone 150 as a fifth application example of the electronic device 50. In an example in FIG. 52, a display surface 2z extends nearly the outer shape size of the electronic device 50, and the width of a bezel 2y around the display surface 2z is set to several millimeters or less. In general, a front camera is often mounted on the bezel 2y, but in FIG. 52, as indicated by a broken line, the image sensor module 9 serving as the front camera is arranged on, for example, the back surface side of a substantially central portion of the display surface 2z. As described above, by providing the front camera on the back surface side of the display surface 2z in this manner, the front camera is no longer necessary to be arranged on the bezel 2y, and thus the width of the bezel 2y can be narrowed.

Note that the present technology may have the following configurations.

(1) An image display device including a plurality of pixels arranged two-dimensionally, in which
the plurality of pixels includes:
a first pixel region including a pixel that includes a first region configured to emit light and a second region configured to transmit visible light;
a second pixel region arranged around the first pixel region, the second pixel region including a pixel configured to emit light with an area larger than a light-emitting area of the pixel in the first pixel region; and
a light shielding layer configured to shield a transistor arranged in the second region from light.

(2) The image display device according to (1), in which the light shielding layer blocks at least one of ambient light or light source light from being incident on the transistor arranged in the second region.

(3) The image display device according to (1) or (2), in which the light shielding layer is arranged so as to block light from being incident on a channel region of the transistor.

(4) The image display device according to (3), in which the light shielding layer has an area equal to or larger than an area of the channel region of the transistor.

(5) The image display device according to (3), in which the light shielding layer is arranged so as to block light from being incident on a lightly doped drain (LDD) region arranged between the channel region and a source region of the transistor and between the channel region and a drain region of the transistor, and the channel region.

(6) The image display device according to (5), in which the light shielding layer has an area equal to or larger than a total area of the channel region of the transistor and the LDD regions on both sides of the channel region.

(7) The image display device according to any one of (1) to (6), in which in a case where a current flows unidirectionally between a drain and a source of the transistor arranged in the second region, the light shielding layer has one end connected to the source and is arranged so as to cover a channel region of the transistor.

(8) The image display device according to any one of (1) to (6), in which in a case where a current flows bidirectionally between a source and a drain of the transistor arranged in the second region, the light shielding layer includes a first light shielding region having one end connected to the source and covering at least a part of a channel region of the transistor and a second light shielding region having one end connected to the drain and covering at least a part of the channel region.

(9) The image display device according to any one of (1) to (8), in which
each of the plurality of pixels includes:
a light emitting element; and
a drive transistor configured to drive the light emitting element, and
the light shielding layer shields the drive transistor arranged in the second region from light.

(10) The image display device according to (9), in which
each of the plurality of pixels includes at least one switch transistor configured to operate in a linear region, and
the light shielding layer shields the switch transistor arranged in the second region from light.

(11) The image display device according to (10), in which the light shielding layer shields, from light, the switch transistor configured to control a gate voltage of the drive transistor.

(12) The image display device according to any one of (9) to (11), further including:
an anode electrode layer of the light emitting element;
a first wiring layer including a gate of the transistor arranged below the anode electrode layer; and
a semiconductor layer including a channel region of the transistor arranged below the first wiring layer, in which
the light shielding layer is arranged below the semiconductor layer to shield the channel region from light.

(13) The image display device according to any one of (9) to (11), further including:
an anode electrode layer of the light emitting element;
a semiconductor layer arranged below the anode electrode layer and including a channel region of the transistor arranged in the second region; and
a first wiring layer including a gate arranged below the semiconductor layer, in which
the light shielding layer is arranged below the first wiring layer to shield the channel region from light.

(14) The image display device according to (12) or (13), further including a second wiring layer arranged above the first wiring layer and the semiconductor layer to shield the channel region from light.

(15) The image display device according to any one of (12) to (14), in which the light shielding layer has an area equal to or larger than an area of the semiconductor layer.

(16) The image display device according to any one of (1) to (15), further including
a display panel including the plurality of pixels, in which
the first pixel region is provided at a plurality of places in the display panel.

(17) An electronic device including:
an image display device including a plurality of pixels arranged two-dimensionally; and
a light receiving device configured to receive light incident through the image display device, in which
the image display device includes the plurality of pixels arranged two-dimensionally, and
the plurality of pixels includes:
a first pixel region including a pixel that includes a first region configured to emit light and a second region configured to transmit visible light;
a second pixel region arranged around the first pixel region, the second pixel region including a pixel configured to emit light with an area larger than a light-emitting area of the pixel in the first pixel region; and
a light shielding layer configured to shield a transistor arranged in the second region from light.

(18) The electronic device according to (17), in which the light receiving device receives light transmitted through the first pixel region.

(19) The electronic device according to (17) or (18), further including a light source configured to emit light of a predetermined wavelength that passes through the first pixel region.

(20) The electronic device according to any one of (17) to (19), in which the light receiving device includes at least one of: an imaging sensor configured to photoelectrically convert light incident through the second region; a distance measuring sensor configured to receive light incident through the second region to measure a distance; or a temperature sensor configured to measure a temperature on the basis of light incident through the second region.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

1 Image display device
2 Display panel
2a Display layer
2b Anode
2c Hole injection layer
2d Hole transport layer
2e Light-emitting layer
2f Electron transport layer
2g Electron injection layer
2h Cathode
2y Bezel
2z Display surface
3 Flexible printed circuit
4 Chip
5 Sensor
6 First pixel region
6a Self light-emitting element
6b First light emitting region (first region)
6b First light emitting region
6c Non-light emitting region (transmissive window, second region)
6c Non-light emitting region
6d Transmissive window
7 Pixel
8 Second pixel region
8a Self light-emitting element
8b Second light emitting region
9 Image sensor module
9a Support substrate
9b Image sensor
9c (Infrared Ray) Cut filter
9d Lens unit
9e Coil
9f Magnet
9g Spring
10 Subject
12 Pixel circuit
31 First transparent substrate
32 First insulating layer
33 First wiring layer
33C Contact region
34 Second insulating layer
34a Trench
35 Second wiring layer (M2)
35a Contact member
35C Second contact region
35D Drain electrode layer
35S Source electrode layer
36 Third insulating layer
36a Trench
36b Contact member
37 Fourth insulating layer
37a Recess
38 Anode electrode layer
39 Cathode electrode layer
40 Fifth insulating layer
41 Second transparent substrate
42 Semiconductor layer
43 Insulating layer
44 Light shielding layer (second light shielding layer)
45 Channel region
46 LDD region
47 Light shielding portion (first light shielding layer)
47C First contact region
50 Electronic device
100 Vehicle
101 Center display
102 Console display
103 Head-up display
104 Digital rear mirror
105 Steering wheel display
106 Rear entertainment display
107 Dashboard
108 Driver seat
109 Passenger seat
110 Center console
111 Shift lever
112 Windshield
113 Steering wheel
120 Digital camera
121 Lens
122 Camera body
123 Grip
124 Electronic viewfinder
125 Shutter
126 Monitor screen
130a Smart glass
131 Mounting member
132 Display device
134 Glasses
135 Main body portion
136 Arm portion
137 Lens barrel portion
138 Lens
150 Smartphone

1. An image display device comprising
a plurality of pixels arranged two-dimensionally, wherein
the plurality of pixels includes:
a first pixel region including a pixel that includes a first region configured to emit light and a second region configured to transmit visible light;
a second pixel region arranged around the first pixel region, the second pixel region including a pixel configured to emit light with an area larger than a light-emitting area of the pixel in the first pixel region; and
a light shielding layer configured to shield a transistor arranged in the second region from light.

2. The image display device according to claim 1, wherein the light shielding layer blocks at least one of ambient light or light source light from being incident on the transistor arranged in the second region.

3. The image display device according to claim 1, wherein the light shielding layer is arranged so as to block light from being incident on a channel region of the transistor.

4. The image display device according to claim 3, wherein the light shielding layer has an area equal to or larger than an area of the channel region of the transistor.

5. The image display device according to claim 3, wherein the light shielding layer is arranged so as to block light from being incident on a lightly doped drain (LDD) region arranged between the channel region and a source region of the transistor and between the channel region and a drain region of the transistor, and the channel region.

6. The image display device according to claim 5, wherein the light shielding layer has an area equal to or larger than a total area of the channel region of the transistor and the LDD regions on both sides of the channel region.

7. The image display device according to claim 1, wherein in a case where a current flows unidirectionally between a drain and a source of the transistor arranged in the second region, the light shielding layer has one end connected to the source and is arranged so as to cover a channel region of the transistor.

8. The image display device according to claim 1, wherein in a case where a current flows bidirectionally between a source and a drain of the transistor arranged in the second region, the light shielding layer includes a first light shielding region having one end connected to the source and covering at least a part of a channel region of the transistor and a second light shielding region having one end connected to the drain and covering at least a part of the channel region.

9. The image display device according to claim 1, wherein
each of the plurality of pixels includes:
a light emitting element; and
a drive transistor configured to drive the light emitting element, and
the light shielding layer shields the drive transistor arranged in the second region from light.

10. The image display device according to claim 9, wherein
each of the plurality of pixels includes at least one switch transistor configured to operate in a linear region, and
the light shielding layer shields the switch transistor arranged in the second region from light.

11. The image display device according to claim 10, wherein the light shielding layer shields, from light, the switch transistor configured to control a gate voltage of the drive transistor.

12. The image display device according to claim 9, further comprising:
an anode electrode layer of the light emitting element;
a first wiring layer including a gate of the transistor arranged below the anode electrode layer; and
a semiconductor layer including a channel region of the transistor arranged below the first wiring layer, wherein
the light shielding layer is arranged below the semiconductor layer to shield the channel region from light.

13. The image display device according to claim 9, further comprising:
an anode electrode layer of the light emitting element;
a semiconductor layer arranged below the anode electrode layer and including a channel region of the transistor arranged in the second region; and
a first wiring layer including a gate arranged below the semiconductor layer, wherein
the light shielding layer is arranged below the first wiring layer to shield the channel region from light.

14. The image display device according to claim 12, further comprising a second wiring layer arranged above the first wiring layer and the semiconductor layer to shield the channel region from light.

15. The image display device according to claim 12, wherein the light shielding layer has an area equal to or larger than an area of the semiconductor layer.

16. The image display device according to claim 1, further comprising
a display panel including the plurality of pixels, wherein
the first pixel region is provided at a plurality of places in the display panel.

17. An electronic device comprising:
an image display device including a plurality of pixels arranged two-dimensionally; and
a light receiving device configured to receive light incident through the image display device, wherein
the image display device includes the plurality of pixels arranged two-dimensionally, and
the plurality of pixels includes:
a first pixel region including a pixel that includes a first region configured to emit light and a second region configured to transmit visible light;
a second pixel region arranged around the first pixel region, the second pixel region including a pixel configured to emit light with an area larger than a light-emitting area of the pixel in the first pixel region; and
a light shielding layer configured to shield a transistor arranged in the second region from light.

18. The electronic device according to claim 17, wherein the light receiving device receives light transmitted through the first pixel region.

19. The electronic device according to claim 17, further comprising a light source configured to emit light of a predetermined wavelength that passes through the first pixel region.

20. The electronic device according to claim 17, wherein the light receiving device includes at least one of: an imaging sensor configured to photoelectrically convert light incident through the second region; a distance measuring sensor configured to receive light incident through the second region to measure a distance; or a temperature sensor configured to measure a temperature on a basis of light incident through the second region.
